(19) United States
(12) Patent Application Publication
(10) Pub. No.: US 2026/0173699 A1
(43) Pub. Date: Jun. 18, 2026

(54) Display Device and Display Panel

(71) Applicant: LG Display Co., Ltd., Seoul (KR)

(72) Inventor: JunHo Youn, Paju-si (KR)

(21) Appl. No.: 19/339,063

(22) Filed: Sep. 24, 2025

(30) Foreign Application Priority Data
Dec. 12, 2024 (KR) 10-2024-0184484

(51) Int. Cl. H10K 59/35

(52) U.S. Cl. CPC H10K 59/353

(57) ABSTRACT

A display device includes a display panel. The display panel includes an optical area having a transmission area and an optical emission area, and a normal area having a normal emission area at an outer periphery of the optical area, wherein the optical emission area includes a pixel in which a plurality of subpixels of different colors are stacked, and the plurality of subpixels emit light at different times.

### CROSS REFERENCE TO RELATED APPLICATIONS

This application claims priority and benefit from Korean Patent Application No. 10-2024-0184484, filed on Dec. 12, 2024, which is hereby incorporated by reference in its entirety for all purposes as if fully set forth herein.

### TECHNICAL FIELD

Exemplary embodiments of the present disclosure relate to a display device and a display panel, and more specifically, to a display device and a display panel capable of improving a transmittance of an area where an optical electronic device is located.

### BACKGROUND

As technology advances, a display device may provide image-capturing functions and various sensing functions in addition to the function of displaying images. To this end, the display device must be equipped with optical electronic devices (also referred to as light receiving devices or sensors) such as cameras and detection sensors.

Since an optical electronic device is required to receive light from the front of a display device, the optical electronic device is required to be installed in a location where light reception is advantageous. Therefore, conventionally, a camera (e.g., camera lens) and a detection sensor had to be installed so that they were exposed on the front of the display device. As a result, a bezel of a display panel has become wider, or a notch or physical hole has been formed in the display area of the display panel, and the camera or detection sensor has been installed there.

Therefore, as the optical electronic device such as the camera or detection sensor receiving light from the front and performing a predetermined function is installed on the display device, the bezel on the front of the display device may become larger, or there is a restriction in designing the front area of the display device.

Accordingly, in the field of display technology, a technology is being developed to provide an optical electronic device such as the camera and detection sensor without reducing the area of the display area of the display panel.

For example, a technology has been proposed in which an optical electronic device such as the camera and detection sensor is located under the display area of the display panel, but subpixels are disposed only in a portion of a light emission area of an optical area overlapping with the optical electronic device, and no subpixels are disposed in the remaining transmission area.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

The inventors of the present application found that, there is a problem that the transmittance of the optical area is reduced due to the emission area formed within the optical area.

Accordingly, the present disclosure proposes a display device and a display panel that improve the transmittance of an optical area where an optical electronic device is located.

Exemplary embodiments of the present disclosure may provide a display device and a display panel capable of expanding the area of the transmission area and improving the transmittance by forming pixels within the optical area into a subpixel stacking structure.

In addition, embodiments of the present disclosure may provide a display device and a display panel capable of time-division driving of subpixels of a stacking structure according to color.

Exemplary embodiments of the present disclosure may provide a display panel including an optical area having a transmission area and an optical emission area, and a normal area having a normal emission area at the periphery of the optical area, wherein the optical emission area includes a pixel in which a plurality of subpixels of different colors are stacked, and the plurality of subpixels emit light at different times.

Exemplary embodiments of the present disclosure may provide a display device including a display panel including an optical area having a transmission area and an optical emission area, and a normal area having a normal emission area at an outer periphery of the optical area, and a driving circuit configured to drive the display panel, wherein the optical emission area includes a pixel in which a plurality of subpixels of different colors are stacked, and the plurality of subpixels emit light at different times.

Exemplary embodiments of the present disclosure may provide a display panel including an optical area including a transmission area and an optical emission area, wherein the optical emission area comprises a pixel in which a first subpixel, a second subpixel and a third subpixel of different colors are stacked, the first subpixel is supplied with a first pixel high-potential voltage and a first pixel low-potential voltage, the second subpixel is supplied with a second pixel high-potential voltage and the first pixel low-potential voltage, and the third subpixel is supplied with the second pixel high-potential voltage and a second pixel low-potential voltage.

According to exemplary embodiments of the present disclosure, it is possible to provide a display device and a display panel that improve the transmittance of an optical area where an optical electronic device is located.

According to exemplary embodiments of the present disclosure, it is possible to provide a display device and a display panel capable of expanding the area of the transmission area and improving the transmittance by forming pixels within the optical area into a subpixel stacking structure.

According to exemplary embodiments of the present disclosure, it is possible to provide a display device and a display panel capable of time-division driving of subpixels of a stacking structure according to color.

In addition, according to exemplary embodiments of the present disclosure, it is possible to provide an effect that enables process optimization through a subpixel stacking structure capable of time-division driving within the optical area.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 illustrates a plan view of a display device according to exemplary embodiments of the present disclosure.

FIG. 2 schematically illustrates a system configuration of a display device according to exemplary embodiments of the present disclosure.

FIG. 3 illustrates an exemplary equivalent circuit of a subpixel in a display panel according to exemplary embodiments of the present disclosure.

FIG. 4 illustrates an example of the arrangement of subpixels in a normal area and a transmission area included in a display area in a display device according to exemplary embodiments of the present disclosure.

FIG. 5 illustrates an exemplary cross-section of a display area in a display panel according to exemplary embodiments of the present disclosure.

FIG. 6 illustrates an exemplary plane of an optical emission area formed in an optical area in a display device according to exemplary embodiments of the present disclosure.

FIG. 7 illustrates an exemplary cross-section of an optical emission area formed in an optical area in a display device according to exemplary embodiments of the present disclosure.

FIG. 8 illustrates an exemplary circuit of a subpixel formed in an optical area in a display device according to exemplary embodiments of the present disclosure.

FIG. 9 illustrates an exemplary plane of an optical emission area formed in an optical area in a display device according to further exemplary embodiments of the present disclosure.

FIG. 10 illustrates an exemplary circuit of a subpixel formed in an optical area in a display device according to further exemplary embodiments of the present disclosure.

FIG. 11 illustrates an exemplary cross-section of an optical emission area formed in an optical area in a display device according to further exemplary embodiments of the present disclosure.

FIGS. 12 to 19 illustrate a manufacturing process of an optical emission area formed in an optical area in a display device according to further exemplary embodiments of the present disclosure.

FIG. 20 illustrates an exemplary signal timing for time-division driving of the first to third light emitting elements of a stacking structure in a display device according to exemplary embodiments of the present disclosure.

FIG. 21 is a plan view illustrating a structure in which a plurality of subpixels overlap with each other for pixels located in an optical area and a normal area in a display device according to exemplary embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and convenience.

### DETAILED DESCRIPTION

Hereinafter, some embodiments of the present disclosure will be described in detail with reference to exemplary drawings. In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions (e.g., lengths, widths, heights, thicknesses, locations, radii, diameters, and areas), relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various embodiments of the present disclosure will be described in detail with reference to the accompanying drawings.

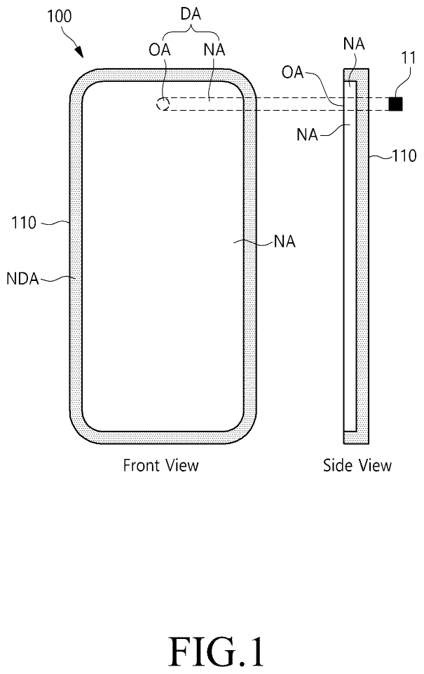

FIG. 1 illustrates a plan view of a display device according to exemplary embodiments of the present disclosure.

Referring to FIG. 1, a display device 100 according to exemplary embodiments of the present disclosure may include a display panel 110 that displays an image and one or more optical electronic devices 11.

The display panel 110 may include a display area DA where an image is displayed and a non-display area NDA where an image is not displayed. In this case, the display area DA may be referred to as an active area.

A plurality of subpixels may be arranged in the display area DA, and various signal lines for driving the plurality of subpixels may be arranged.

The non-display area NDA may be an area outside the display area DA. Various signal lines may be arranged in the non-display area NDA, and various driving circuits may be connected thereto. At least a portion of the non-display area NDA may be bent so as not to be visible from the front, or may be covered by a case (not shown). The non-display area NDA may be also referred to as a bezel or an edge area.

In the display device 100 according to the exemplary embodiments of the present disclosure, one or more optical electronic devices 11 may be electronic components located below (e.g., opposite of the viewing surface) the display panel 110, without being limited thereto. Alternatively, the optical electronic devices 11 may be integrally formed with the display panel 110.

Light may enter the front side (e.g., viewing surface) of the display panel 110, pass through the display panel 110, and be transmitted to one or more optical electronic devices 11 positioned below (e.g., opposite of the viewing surface) the display panel 110.

The one or more optical electronic devices 11 may be devices that receive light passing through the display panel 110 and perform a predetermined function according to the received light. For example, the one or more optical electronic devices 11 may include one or more of a photographing device such as a camera (or image sensor), a detection sensor such as a proximity sensor, and an illuminance sensor, etc.

In the display panel 110 according to the exemplary embodiments of the present disclosure, the display area DA may include a normal area NA and one or more optical areas OA.

Hereinafter, for convenience of descriptions related to shapes of the one or more optical areas OA, each of one or more optical areas OA is considered to have a circular shape. It should be, however, understood that the scope of the present disclosure includes examples where at least one of one or more optical areas OA have a shape other than a circular shape, such as an ellipse, a quadrangle, a hexagon, an octagon or the like, without being limited thereto.

The one or more optical areas OA may be areas overlapping with one or more optical electronic devices 11.

The display area DA may include a normal area NA and an optical area OA. Here, at least a portion of the optical area OA may overlap with an optical electronic device 11. FIG. 1 illustrates a front view and a side view of the example display device according to aspects of the present disclosure.

In the display device 100 according to the exemplary embodiments of the present disclosure, if the optical electronic device 11 that is not exposed to the outside and is hidden under the display panel 110 is a camera, the display device 100 according to the exemplary embodiments of the present disclosure may be referred to as a display to which an under-display camera (UDC) technology is supplied.

Accordingly, in the case of the display device 100 according to the exemplary embodiments of the present disclosure, since a notch or camera hole for camera exposure does not need to be formed in the display panel 110, the area of the display area DA may not decrease.

Accordingly, since a notch or camera hole for camera exposure does not need to be formed in the display panel 110, the size of the bezel area can be reduced, and design constraints may be eliminated, thereby increasing the degree of freedom in design.

In the display device 100 according to the exemplary embodiments of the present disclosure, even though one or more optical electronic devices 11 are hidden and positioned behind the display panel 110, one or more optical electronic devices 11 is required to normally receive light and normally perform a corresponding function, but is not limited thereto. For example, one or more optical electronic devices 11 can receive light that has passed through the display panel 110.

In one or more aspects, the one or more optical electronic devices 11 that need to receive light may be exposed in the front surface (viewing surface) of the display panel 110 or the display device 100.

In addition, in the display device 100 according to the exemplary embodiments of the present disclosure, even though one or more optical electronic devices 11 are positioned hidden behind the display panel 110 and overlap with the display area DA, normal image display should be possible in one or more optical areas OA overlapping with one or more optical electronic devices 11 in the display area DA.

In one example, one or more optical electronic devices 11 may be, for example, a camera or a sensor, without being limited thereto. For example, the sensor may be a proximity sensor, an illuminance sensor, an infrared sensor, and/or the like. For example, the camera may be a camera lens, an image sensor, or a unit including at least one of the camera lens and the image sensor, but is not limited thereto.

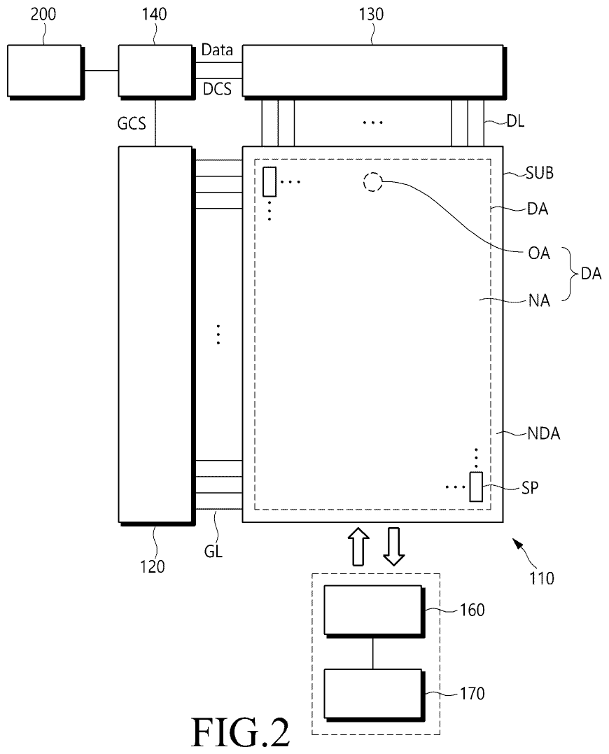

FIG. 2 schematically illustrates a system configuration of a display device according to exemplary embodiments of the present disclosure.

Referring to FIG. 2, the display device 100 according to the exemplary embodiments of the present disclosure may include a display panel 110 and a display driving circuit as components for image display.

The display driving circuit may include, but is not limited to, a gate driving circuit 120, a data driving circuit 130, and a display controller 140 as a circuit for driving the display panel 110.

The display panel 110 may include a display area DA where an image is displayed and a non-display area NDA where an image is not displayed. The non-display area NDA may be an outer area of the display area DA and may also be referred to as an edge area or a bezel area. All or part of the non-display area NDA may be an area visible from the front surface of the display device 100, or may be an area that is bent and not visible from the front surface of the display device 100 or an area that is covered by a case or housing (not shown) of the display device 100.

The display panel 110 may include a substrate SUB and a plurality of subpixels SP arranged on the substrate SUB, without being limited thereto. In addition, the display panel 110 may further include various types of signal lines in order to drive the plurality of subpixels SP. For example, the display panel 110 may include one or more optical areas.

The display device 100 according to the exemplary embodiments of the present disclosure may be a liquid crystal display device (LCD), a plasma display device (PDP), a field emission display device (FED), or may be a self-luminous display device in which the display panel 110 emits light by itself, such as an organic light-emitting display device (OLED), and a micro LED (Micro Light Emitting Diode) display device. In the case that the display device 100 according to the exemplary embodiments of the present disclosure is a self-luminous display device, each of the plurality of subpixels SP may include a light emitting element.

For example, the display device 100 according to the exemplary embodiments of the present disclosure may be an organic light-emitting display device in which the light emitting element is implemented as an organic light-emitting diode (OLED). For another example, the display device 100 according to the exemplary embodiments of the present disclosure may be an inorganic light-emitting display device in which the light emitting element is implemented as an inorganic-based material light-emitting diode. For another example, the display device 100 according to the exemplary embodiments of the present disclosure may be a quantum dot display device in which the light emitting element is implemented as a quantum dot, which is a semiconductor crystal that emits light by itself. However, the present disclosure is not limited thereto.

The structure of each of the plurality of subpixels SP may vary depending on the type of the display device 100. For example, if the display device 100 is a self-luminous display device in which the subpixels SP emit light by themselves, each subpixel SP may include a light emitting element that emits light by itself, one or more transistors, and one or more capacitors.

For example, various types of signal lines may include a plurality of data lines DL that transmit data signals (also referred to as data voltages or image signals) and a plurality of gate lines GL that transmit gate signals (also referred to as scan signals), and the like.

A plurality of data lines DL and a plurality of gate lines GL may intersect each other. Each of the plurality of data lines DL may be arranged while extending in a first direction. Each of the plurality of gate lines GL may be arranged while extending in a second direction different from the first direction.

Here, the first direction may be a column direction and the second direction may be a row direction, without being limited thereto. Alternatively, the first direction may be a row direction and the second direction may be a column direction.

The data driving circuit 130 may be a circuit for driving the plurality of data lines DL, and may output data signals to the plurality of data lines DL. The gate driving circuit 120 may be a circuit for driving the plurality of gate lines GL, and may output gate signals to the plurality of gate lines GL.

The display controller 140 may be a device for controlling the data driving circuit 130 and the gate driving circuit 120, and may control the driving timing for a plurality of data lines DL and the driving timing for a plurality of gate lines GL.

The display controller 140 may supply a data driving control signal DCS to the data driving circuit 130 to control the data driving circuit 130, and may supply a gate driving control signal GCS to the gate driving circuit 120 to control the gate driving circuit 120.

The display controller 140 may receive input image data from a host system 200, and may supply image data Data to the data driving circuit 130 based on the input image data.

The data driving circuit 130 may supply data signals to a plurality of data lines DL according to the driving timing control of the display controller 140.

The data driving circuit 130 may receive image data Data in digital form from the display controller 140, convert the received image data Data into data signals in analog form, and output the converted analog data signals to a plurality of data lines DL.

The gate driving circuit 120 may supply gate signals to a plurality of gate lines GL according to the timing control of the display controller 140. The gate driving circuit 120 may receive a first gate voltage corresponding to a turn-on level voltage and a second gate voltage corresponding to a turn-off level voltage together with various gate driving control signals GCS, generate gate signals, and supply the generated gate signals to a plurality of gate lines GL.

For example, the data driving circuit 130 may be connected to the display panel 110 in a tape automated bonding (TAB) manner, connected to a bonding pad of the display panel 110 in a chip-on-glass (COG) or chip-on-panel (COP) manner, or connected to the display panel 110 by a chip-on-film (COF) manner.

The gate driving circuit 120 may be connected to the display panel 110 by a tape automated bonding (TAB) method, connected to a conductive pad such as a bonding pad of the display panel 110 by a chip-on-glass (COG) or chip-on-panel (COP) method, or connected to the display panel 110 by a chip-on-film (COF) method.

Alternatively, the gate driving circuit 120 may be formed in a non-display area NDA of the display panel 110 by a gate-in-panel (GIP) type. The gate driving circuit 120 may be disposed on or connected to the substrate, but is not limited thereto. Alternatively, the gate driving circuit 230 may be disposed in the display area DA of the display panel 110. That is, the gate driving circuit 120 may be disposed in the non-display area NDA of the substrate if it is a GIP type. The gate driving circuit 120 may be connected to the substrate if it is a chip-on-glass (COG) type, a chip-on-film (COF) type, etc.

Meanwhile, at least one of the data driving circuit 130 and the gate driving circuit 120 may be disposed in the display area DA of the display panel 110. For example, at least one of the data driving circuit 130 and the gate driving circuit 120 may be disposed so as not to overlap with the subpixels SP, or may be disposed so as to partially or completely overlap with the subpixels SP.

The data driving circuit 130 may be connected to one side or portion (e.g., the upper side or the lower side) of the display panel 110. Depending on the driving method, panel design method, etc., the data driving circuit 130 may be connected to, but not limited to, both sides or portions (e.g., the upper side and the lower side) of the display panel 110, or may be connected to two or more sides among the four sides (e.g., the upper edge, the lower edge, a left edge, and a right edge) of the display panel 110.

In one or more aspects, the data driving circuit 130 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique, without being limited thereto.

The gate driving circuit 120 may be connected to one side (e.g., left or right) of the display panel 110, without being limited thereto. Also, the gate driving circuit 120 may be connected to, but not limited to, at least two of four sides or portions (e.g., an upper edge, a lower edge, the left edge, and the right edge) of the display panel 110 according to driving schemes, panel design schemes, or the like. For example, depending on the driving method, panel design method, etc., the gate driving circuit 120 may be connected to both sides (e.g., left and right) of the display panel 110.

The display controller 140 may be implemented as a separate component from the data driving circuit 130, or may be implemented as an integrated circuit by being integrated with the data driving circuit 130.

The display controller 140 may be a timing controller used in conventional display technology, or may be a control device capable of performing other control functions including a timing controller, or may be a control device other than the timing controller or a circuit within the control device. The display controller 140 may be implemented as various circuits or electronic components such as an integrated-circuit (IC), a field programmable gate array (FPGA), an application specific integrated-circuit (ASIC), or a processor, without being limited thereto.

For example, the display controller 140 may be implemented in a separate component from the data driving circuit 130, or incorporated in the data driving circuit 130 and thus implemented in an integrated circuit, but is not limited thereto.

The display controller 140 may be mounted on a printed circuit board or a flexible printed circuit, and may be electrically connected to the data driving circuit 130 and the gate driving circuit 120 through the printed circuit board or the flexible printed circuit, and/or the like.

The display controller 140 may transmit and receive signals with the data driving circuit 130 according to one or more predefined interfaces. Here, for example, the interface may include an LVDS (Low Voltage Differential Signaling) interface, an EPI interface, an SP (Serial Peripheral) interface, etc. Similarly, the display controller 140 can transmit signals to, and receive signals from, the gate driving circuit 120 via one or more predefined interfaces.

The display device 100 according to the exemplary embodiments of the present disclosure may include a touch sensor and a touch circuit that senses the touch sensor to detect an occurrence of a touch by a touch object such as a finger or a pen or detects a touch position (or touch coordinates) in order to provide a touch sensing function in addition to an image display function.

The touch circuit may include, but is not limited to, a touch driving circuit 160 that drives and senses the touch sensor to generate and output touch sensing data, and a touch controller 170 that detects a touch occurrence or a touch position (or touch coordinates) using the touch sensing data, and one or more other components.

The touch sensor may include, but is not limited to, a plurality of touch electrodes. The touch sensor may further include a plurality of touch lines for electrically connecting a plurality of touch electrodes and a touch driving circuit 160.

The touch sensor may be present in the form of a touch panel on the outside of the display panel 110, or may be present inside the display panel 110. If the touch sensor is present in the form of a touch panel on the outside of the display panel 110, the touch sensor may be referred to as an external type. If the touch sensor is an external type, the touch panel and the display panel 110 may be manufactured separately and combined during the assembly process. The external type touch panel may include a substrate for a touch panel and a plurality of touch electrodes on the substrate for the touch panel.

If the touch sensor is present inside the display panel 110, the touch sensor may be formed on the substrate SUB together with signal lines and electrodes related to display driving during the manufacturing process of the display panel 110.

The touch driving circuit 160 may supply a touch driving signal to at least one of the plurality of touch electrodes and generate touch sensing data by sensing at least one of the plurality of touch electrodes.

The touch sensing circuit can perform touch sensing. For example, the touch circuit may perform touch sensing in a self-capacitance sensing manner or a mutual-capacitance sensing manner, without being limited thereto.

If the touch circuit performs touch sensing in a self-capacitance sensing manner, the touch circuit may perform touch sensing based on the capacitance between each touch electrode and a touch object (e.g., a finger, a pen, etc.).

According to the self-capacitance sensing manner, each of the plurality of touch electrodes may act as a driving touch electrode and also act as a sensing touch electrode. The touch driving circuit 160 may drive all or part of the plurality of touch electrodes and sense all or part of the plurality of touch electrodes.

If the touch circuit performs touch sensing in a mutual-capacitance sensing manner, the touch circuit may perform touch sensing based on the capacitance between the touch electrodes.

According to the mutual-capacitance sensing manner, a plurality of touch electrodes may be divided into driving touch electrodes and sensing touch electrodes. The touch driving circuit 160 may drive the driving touch electrodes and sense the sensing touch electrodes.

The touch driving circuit 160 and the touch controller 170 included in the touch circuit may be implemented as separate devices or as one device. In addition, the touch driving circuit 160 and the data driving circuit 130 may be implemented as separate devices or as one device.

The display device 100 may further include a power supply circuit that supplies various types of power to the display driving circuit and/or the touch circuit.

The display device 100 according to the exemplary embodiments of the present disclosure may be a mobile terminal such as a notebook computer, a smart phone or tablet, or a monitor or television (TV) of various sizes, and may be a display of various types, shapes and sizes capable of displaying information or images, without being limited thereto.

As described above, the display area DA in the display panel 110 may include a normal area NA and one or more optical areas OA.

The normal area NA and one or more optical areas OA may be areas capable of displaying images. However, the normal area NA may be an area where a light-transmitting structure does not need to be formed, and the one or more optical areas OA may be areas where a light-transmitting structure is required to be formed.

As described above, the display area DA in the display panel 110 may include one or more optical areas OA together with the normal area NA, but for convenience of explanation.

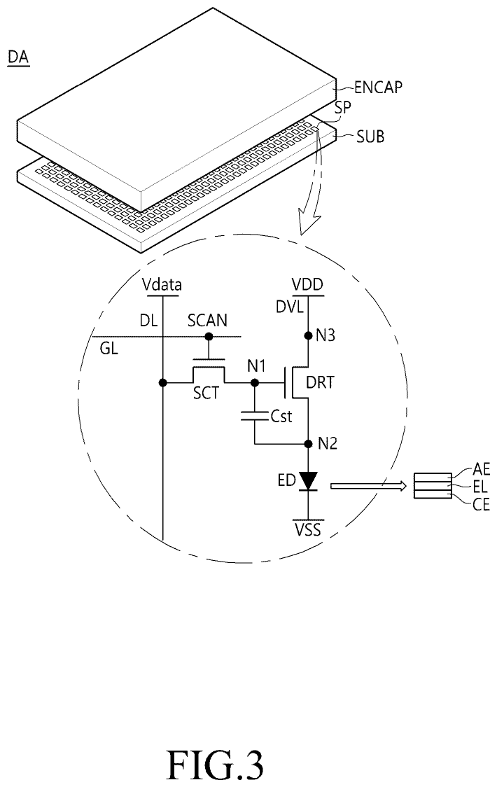

FIG. 3 illustrates an equivalent circuit of a subpixel in a display panel according to exemplary embodiments of the present disclosure as an example.

Referring to FIG. 3, in the display panel 110 according to the exemplary embodiments of the present disclosure, each of the subpixels SP arranged

in the display area DA may include a light emitting element ED, a driving transistor DRT for driving the light emitting element ED, a scan transistor SCT for transmitting a data voltage Vdata to a first node N1 of the driving transistor DRT, and a storage capacitor Cst for maintaining a constant voltage during one frame, but is not limited thereto. More or less elements can be included.

The driving transistor DRT may be connected between a second node N2 and a third node N3. The driving transistor DRT may include a first node N1 to which a data voltage Vdata may be supplied, a second node N2 electrically connected to the light emitting element ED, and a third node N3 to which a driving voltage ELVDD is supplied from a driving voltage line DVL. In the driving transistor DRT, the first node N1 may be a gate node, the second node N2 may be a source node or a drain node, and the third node N3 may be a drain node or a source node.

The light emitting element ED may be disposed between the second node N2 and power line supplied with the pixel low-potential voltage EVSS. The light emitting element ED may include an anode electrode AE, an emission layer EL, and a cathode electrode CE. The anode electrode AE may be a pixel electrode disposed in each subpixel SP and may be electrically connected to the second node N2 of the driving transistor DRT of each subpixel SP. The cathode electrode CE may be a common electrode arranged in common to a plurality of subpixels SP, and may be supplied with a pixel low-potential voltage EVSS.

For example, the emission layer EL may include one or more of a hole injection layer (HIL), a hole transmitting layer (HTL), an electron transmitting layer (ETL) and an electron injection layer (EIL), but the present disclosure is not limited thereto.

For example, the anode electrode AE may be a pixel electrode, and the cathode electrode CE may be a common electrode. Alternatively, the anode electrode AE may be a common electrode, and the cathode electrode CE may be a pixel electrode.

For example, the light emitting element ED may be an organic light-emitting diode (OLED), an inorganic light-emitting diode, or a quantum dot light emitting element. In this case, if the light emitting element ED is an organic light-emitting diode, the emission layer EL in the light emitting element ED may include an organic emission layer containing an organic material. Alternatively, if the light emitting element ED is an inorganic light-emitting diode, the emission layer EL in the light emitting element ED may include an inorganic emission layer containing an

inorganic material.

The scan transistor SCT may be disposed between the first node N1 and the data line DL. The scan transistor SCT may be turned on and off by a scan signal SCAN, which is a gate signal supplied through a gate line GL, and may be electrically connected between the first node N1 of the driving transistor DRT and the data line DL.

For example, when scan transistor SCT is turned on in response to scan signal SCAN, the data voltage Vdata may be applied to the first node N1 of the driving transistor DRT.

The storage capacitor Cst may be electrically connected between the first node N1 and the second node N2 of the driving transistor DRT.

Each subpixel SP may have a 2T-1C structure including two transistors (e.g., DRT and SCT) and one capacitor Cst as illustrated in FIG. 3, and may further include one or more transistors or one or more capacitors, depending on the case. For example, 3T1C, 4T1C, 5T1C, 3T2C, 4T2C, 5T2C, 6T2C, 7T1C, 7T2C, 8T2C structures, etc. are also possible. And more or less transistors and capacitors could be included.

The storage capacitor Cst may be an external capacitor intentionally designed outside the driving transistor DRT, rather than a parasitic capacitor (e.g., Cgs, Cgd) that may exist between the first node N1 and the second node N2 of the driving transistor DRT.

Each of the driving transistor DRT and the scan transistor SCT may be an n-type transistor or a p-type transistor.

Since the circuit elements (particularly, the light emitting element ED) in each subpixel SP are vulnerable to external moisture or oxygen, an encapsulation layer ENCAP may be disposed on the display panel 110 to prevent external moisture or oxygen from penetrating into the circuit elements (particularly, the light emitting element ED). The encapsulation layer ENCAP may be disposed in a form that covers the light emitting elements ED.

The encapsulation layer ENCAP may include a plurality of encapsulation layers including at least one inorganic encapsulation layer, and at least one organic encapsulation layer. For example, the encapsulation layer ENCAP may have a structure in which at least one organic encapsulation layer is disposed between inorganic encapsulation layers, but is not limited thereto.

The display device according to the exemplary embodiments of the present disclosure can expand the area of the transmission area TA within the optical area OA and improve the transmittance by forming pixels located within the optical area OA in a subpixel stacking structure.

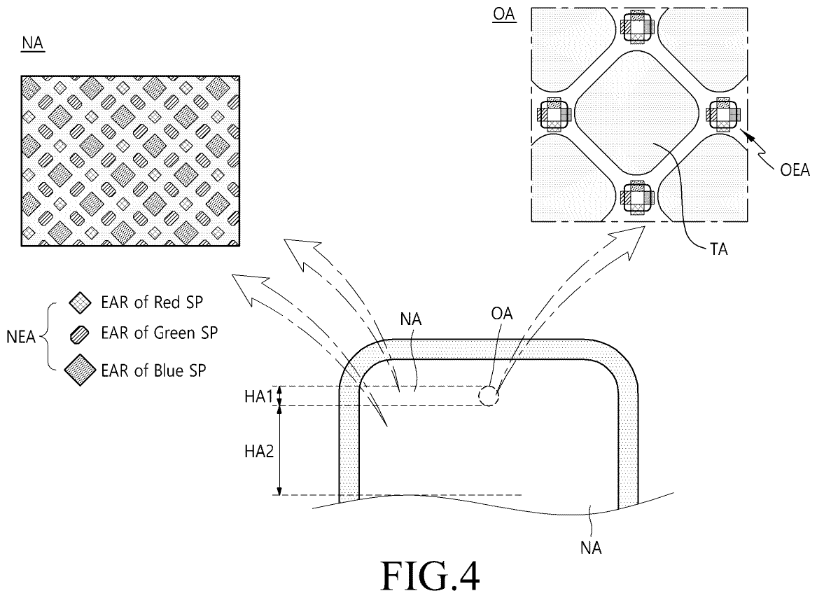

FIG. 4 illustrates an example of the arrangement of subpixels in a normal area and a transmission area included in a display area in a display device according to exemplary embodiments of the present disclosure.

Referring to FIG. 4, in the display panel 110 according to the exemplary embodiments of the present disclosure, a plurality of pixels may be disposed in each of the normal area NA, the optical area OA included in the display area DA.

Each pixel may include a plurality of subpixels SP that emit light of different colors. For example, one pixel may include a red subpixel that emits red light, a green subpixel that emits green light, and a blue subpixel that emits blue light, but is not limited thereto.

Alternatively, each pixel may display one color among cyan, magenta and yellow. In various embodiments, each pixel may display one color among red, green, blue and white.

In this case, an emission area EA formed within the normal area NA may be referred to as a normal emission area NEA, and an emission area EA formed within the optical area OA may be referred to as an optical emission area OEA.

The normal emission area NEA within the normal area NA may include an emission area EAR of the red subpixel, an emission area EAG of the green subpixel, and an emission area EAB of the blue subpixel, and the emission areas EAR, EAG, and EAB of the subpixels emitting lights of different colors may be disposed so as not to overlap with each other on the plane.

The normal area NA may not include a light-transmitting structure, but may include a normal emission area NEA.

Meanwhile, the optical area OA is required to include not only the optical emission area OEA, but also the light-transmitting structure. Therefore, the optical area OA may include an optical emission area OEA and a transmission area TA.

The optical emission area OEA and the transmission area TA may be distinguished based on whether light is transmittable. That is, the optical emission area OEA may be an area that is not transmittable, and the transmission area TA may be an area that is transmittable.

Since the optical area OA includes the transmission area TA, the optical area OA may be an area that is transmittable. In the exemplary embodiments of the present disclosure, the transmission area TA may be referred to as a transparent area, and the transmittance may also be referred to as transparency.

In this case, if the area of the optical emission area OEA in the optical area OA is large, the area of the transmission area TA may decrease, so in order to increase the transmittance of the optical area OA, it is necessary to reduce the area of the optical emission area OEA and increase the area of the transmission area TA.

In embodiments of the present disclosure, when forming an optical emission area OEA within an optical area OA, a pixel may be formed so that subpixels of different colors (e.g., red subpixels, green subpixels, and blue subpixels) overlap with each other to increase the area of the transmission area TA, thereby improving the transmittance of the optical area OA.

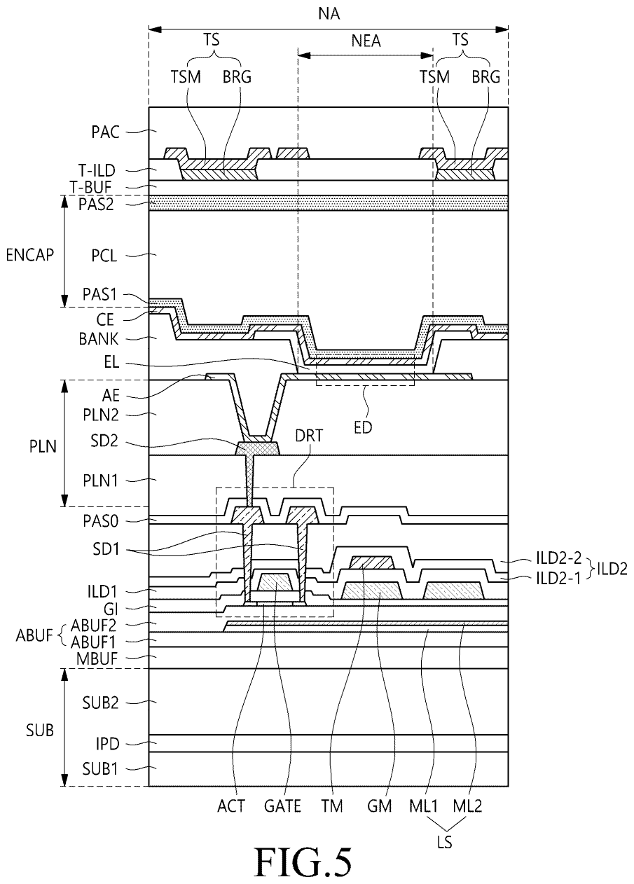

FIG. 5 illustrates an example of a cross-section of a normal area in a display area in a display panel according to exemplary embodiments of the present disclosure.

Here, it is illustrated the normal area NA excluding the optical area OA where the optical electronic device 11 is located.

Referring to FIG. 5, the display panel 110 according to exemplary embodiments of the present disclosure may include a substrate SUB, a driving transistor DRT, a planarization layer PLN, a light emitting element ED, an encapsulation layer ENCAP, and a touch layer.

The substrate SUB may include a first substrate SUB1, a substrate insulating film IPD, and a second substrate SUB2. The substrate insulating film IPD may be located between the first substrate SUB1 and the second substrate SUB2.

The moisture penetration may be prevented by configuring the substrate SUB with a first substrate SUB1, a substrate insulating film IPD, and a second substrate SUB2.

For example, the first substrate SUB1 and the second substrate SUB2 may be polyimide (PI) substrates. The first substrate SUB1 may be referred to as a primary PI substrate, and the second substrate SUB2 may be referred to as a secondary PI substrate.

Various patterns (e.g., ACT, SD1 and GATE), various insulating films (e.g., MBUF, ABUF1, ABUF2, GI, ILD1, ILD2 and PAS0), and various metal patterns (e.g., TM, GM, ML1 and ML2) for forming transistors such as a driving transistor DRT may be disposed on the substrate SUB.

A buffer layer BUF may be disposed on the substrate SUB. For example, a multi-buffer layer MBUF of the buffer layer BUF may be disposed on the second substrate SUB2 of the substrate SUB, and a first active buffer layer ABUF1 of the buffer layer BUF may be disposed on the multi-buffer layer MBUF.

A plurality of metal layers may be disposed on the first active buffer layer ABUF1. For example, a first metal layer ML1 and a second metal layer ML2 may be disposed on the first active buffer layer ABUF1, but is not limited thereto. More or less metal layers may be disposed on the first active buffer layer ABUF1. Here, the first metal layer ML1 and the second metal layer ML2 may be a light shield layer LS for shielding the light.

A second active buffer layer ABUF2 of the buffer layer BUF may be disposed on the first metal layer ML1 and the second metal layer ML2. For example, the second active buffer layer ABUF2 may be disposed to cover the first metal layer ML1 and the second metal layer ML2 and a portion of the first active buffer layer ABUF1. A driving transistor DRT may be disposed on the second active buffer layer ABUF2. An active layer ACT of a driving transistor DRT may be disposed on the second active buffer layer ABUF2.

A gate insulating film GI may be disposed while covering the active layer ACT.

The gate insulating film GI is an insulating layer for insulating the active layer ACT and the gate electrode GATE of a driving transistor DRT from each other, and may be composed of a single layer or multilayers of silicon oxide SiOx or silicon nitride SiNx, but is not limited thereto.

A gate electrode GATE of a driving transistor DRT may be disposed on the gate insulating film GI. In this case, at a position different from the formation position of the driving transistor DRT, a gate material layer GM may be disposed on the gate insulating film GI together with the gate electrode GATE of the driving transistor DRT.

A first interlayer insulating film ILD1 may be disposed while covering the gate electrode GATE and the gate material layer GM. A metal pattern TM may be disposed on the first interlayer insulating film ILD1. The metal pattern TM may be located at a position different from the formation position of the driving transistor DRT.

A second interlayer insulating film ILD2 may be disposed while covering the metal pattern TM on the first interlayer insulating film ILD1.

For example, the second interlayer insulating film ILD2 may be disposed on the metal pattern TM and a portion of the first interlayer insulating film ILD1.

Two first source-drain electrode patterns SD1 may be disposed on the second interlayer insulating film ILD2. One of the two first source-drain electrode patterns SD1 is a source node of a driving transistor DRT, and the other is a drain node of the driving transistor DRT.

One of the two first source-drain electrode patterns SD1 may be electrically connected to one side of the active layer ACT, and the other may be electrically connected to the other side of the active layer ACT. The two first source-drain electrode patterns SD1 may be electrically connected to one side and the other side of the active layer ACT, respectively, through contact holes passing through the second interlayer insulating film ILD2, the first interlayer insulating film ILD1, and the gate insulating film GI.

Meanwhile, the second interlayer insulating film ILD2 may include a second-1 interlayer insulating film ILD2-1 and a second-2 interlayer insulating film ILD2-2. The second-1 interlayer insulating film ILD2-1 may be disposed while covering the metal pattern TM. The second-1 interlayer insulating film ILD2-1 may be disposed to cover the metal pattern TM and a portion of the first interlayer insulating film ILD1 exposed by the metal pattern TM. The second-2 interlayer insulating film ILD2-2 may be positioned on the second-1 interlayer insulating film ILD2-1.

A portion of the active layer ACT overlapping with the gate electrode GATE may be a channel area. One of the two first source-drain

electrode patterns SD1 may be connected to one side of the channel area in the active layer ACT, and the other of the two first source-drain electrode patterns SD1 may be connected to the other side of the channel area in the active layer ACT.

A passivation layer PAS0 may be disposed while covering the two first source-drain electrode patterns SD1. A planarization layer PLN may be disposed on the passivation layer PAS0. For example, the passivation layer PAS0, which is a kind of dielectric (e.g., an inorganic dielectric), may be constituted by a single layer made of a silicon oxide (SiOx) film, a silicon nitride (SiNx) film, or a silicon oxynitride (SiOxNy) film or a multilayer film thereof, etc.

The planarization layer PLN may include plurality planarization layers, such as a first planarization layer PLN1 and a second planarization layer PLN2, but is not limited thereto. More or less planarization layers can be included. The planarization layer PLN may be formed of an organic insulating material such as an acrylic resin.

For example, the planarization layer PLN may be formed of one or more materials of epoxy resin, phenolic resin, polyamides resin, unsaturated polyesters resin, polyphenylene resin, polyphenylene sulfides resin, and benzocyclobutene, but embodiments are not limited thereto.

The first planarization layer PLN1 may be disposed on the passivation layer PAS0.

A second source-drain electrode pattern SD2 may be disposed on the first planarization layer PLN1. The second source-drain electrode pattern SD2 may be connected to one of the two first source-drain electrode patterns SD1 (corresponding to the second node N2 of the driving transistor DRT in the subpixel SP of FIG. 3) through a contact hole passing through the first planarization layer PLN1.

The second planarization layer PLN2 may be disposed while covering the second source-drain electrode pattern SD2. A light emitting element ED may be disposed on the second planarization layer PLN2.

The light emitting element ED may include an anode electrode AE, an emission layer EL, and a cathode electrode CE. For example, the emission layer EL may be disposed between the anode electrode AE and the cathode electrode CE.

The anode electrode AE may be disposed on the second planarization layer PLN2. The anode electrode AE may be electrically connected to the second source-drain electrode pattern SD2 through a contact hole passing through the second planarization layer PLN2.

The bank BANK may be disposed while covering a part of the anode electrode AE. The bank BANK may be disposed to cover a part of the anode electrode AE and a part of the second planarization layer PLN2. A part of the bank BANK corresponding to the emission area EA of the subpixel SP may be opened or removed. For example, the bank BANK may be not disposed in the emission area EA of the subpixel SP.

A part of the anode electrode AE may be exposed to an opening (or open portion) of the bank BANK. For example, in the emission area EA of the subpixel SP, a part of the anode electrode AE may be exposed to an opening of the bank BANK.

An emission layer EL may be located on the side of the bank BANK and the opening (or open portion) of the bank BANK. All or part of the emission layer EL may be located between adjacent banks BANK. The emission layer EL may include an organic film.

In the opening of the bank BANK, the emission layer EL may be in contact with the anode electrode AE. A cathode electrode CE may be disposed on the emission layer EL. For example, the cathode electrode CE may be disposed on the emission layer EL and a part of the bank BANK.

An encapsulation layer ENCAP may be disposed on the light emitting element ED.

The encapsulation layer ENCAP may have a single-layer structure or a multi-layer structure. For example, the encapsulation layer ENCAP may include a first encapsulation layer PAS1, a second encapsulation layer PCL, and a third encapsulation layer PAS2, but is not limited thereto. For example, the second encapsulation layer PCL may be disposed between the first encapsulation layer PAS1 and the third encapsulation layer PAS2. More or less encapsulation layers can be included.

For example, the first encapsulation layer PAS1 and the third encapsulation layer PAS2 may be inorganic films, and the second encapsulation layer PCL may be an organic film. Among the first encapsulation layer PAS1, the second encapsulation layer PCL, and the third encapsulation layer PAS2, the second encapsulation layer PCL may be the thickest, but is not limited thereto. Accordingly, the second encapsulation layer PCL may function as a planarization layer.

The first encapsulation layer PAS1 may also be referred to as a first inorganic encapsulation layer, the second encapsulation layer PCL may also be referred to as an organic encapsulation layer, and the third encapsulation layer PAS2 may also be referred to as a second inorganic encapsulation layer.

The first encapsulation layer PAS1 may be disposed on the cathode electrode CE and may be disposed closest to the light emitting element ED. The first encapsulation layer PAS1 may be formed of an inorganic insulating material capable of low-temperature deposition. For example, the first encapsulation layer PAS1 may be silicon nitride (SiNx), silicon oxide (SiOx), silicon oxynitride (SiON), or aluminum oxide (Al2O3). Since the first encapsulation layer PAS1 is deposited in a low-temperature atmosphere, the first encapsulation layer PAS1 may prevent the emission layer EL including an organic material vulnerable to a high-temperature atmosphere from being damaged during the deposition process.

The second encapsulation layer PCL may be disposed on the first encapsulation layer PAS1. The second encapsulation layer PCL may be formed with a smaller area than the first encapsulation layer PAS1. In this case, the second encapsulation layer PCL may be formed to expose both ends of the first encapsulation layer PAS1. Among the first encapsulation layer PAS1, the second encapsulation layer PCL, and the third encapsulation layer PAS2, the second encapsulation layer PCL may be the thickest. The second encapsulating layer PCL may act as a buffer to relieve stress between each layer due to bending of the display device 100, and may also serve to enhance flattening performance.

For example, the second encapsulation layer PCL may be formed of an acrylic resin, an epoxy resin, a polyimide, polyethylene, or silicon oxycarbon (SiOC), and may be formed of an organic insulating material. For example, the second encapsulation layer PCL may be formed through an inkjet method.

The third encapsulation layer PAS2 may be formed on the second encapsulation layer PCL to cover the upper surface and side surfaces of each of the second encapsulation layer PCL and the first encapsulation layer PAS1. The third encapsulation layer PAS2 may minimize or block external moisture or oxygen from penetrating into the first encapsulation layer PAS1 and the second encapsulation layer PCL.

For example, the third encapsulation layer PAS2 may be formed of an inorganic insulating material such as silicon nitride (SiNx), silicon oxide (SiOx), silicon oxynitride (SiON), or aluminum oxide (Al₂O₃), but is not limited thereto.

Meanwhile, the display device 100 of the present disclosure may have a touch sensor TS formed on the encapsulation layer ENCAP to detect a touch of a user's finger or pen.

If the touch sensor TS is of a type built into the display panel 110, the touch sensor TS may be disposed on the encapsulation layer ENCAP. It will be described the touch sensor structure in detail as follows.

A touch buffer film T-BUF may be disposed on the encapsulation layer ENCAP. Specifically, the touch buffer film T-BUF may be disposed on the third encapsulation layer PAS2.

A touch sensor TS may be disposed on the touch buffer film T-BUF.

The touch sensor TS may include a touch sensor metal TSM and a bridge metal BRG positioned in different layers. The touch sensor metal TSM may be disposed on the bridge metal BRG and a portion of the touch interlayer insulating film T-ILD.

The touch sensor metal TSM and the bridge metal BRG may be formed of a triple structure of Ti/Al/Ti.

A touch interlayer insulating film T-ILD may be disposed between the touch sensor metal TSM and the bridge metal BRG.

The touch interlayer insulating film T-ILD may be formed of an inorganic material such as silicon nitride (SiNx) or silicon oxide (SiOx). In this case, the touch interlayer insulating film T-ILD may be formed of an inorganic material such as silicon oxide (SiOx) to improve touch performance.

For example, the touch sensor TS may include a first touch sensor metal, a second touch sensor metal, and a third touch sensor metal that are positioned adjacent to each other.

If a third touch sensor metal is present between the first touch sensor metal and the second touch sensor metal, and the first touch sensor metal and the second touch sensor metal are to be electrically connected to each other, the first touch sensor metal and the second touch sensor metal may be electrically connected to each other through a bridge metal BRG in a different layer.

The bridge metal BRG may be insulated from the third touch sensor metal by a touch interlayer insulating film T-ILD.

When a touch sensor TS is formed on a display panel 110, a chemical solution (e.g., developer solution or etchant, etc.) used in the process or moisture may be generated from the outside.

Since the touch sensor TS is disposed on a touch buffer film T-BUF, the chemical solution or moisture may be prevented from penetrating into the emission layer EL including an organic substance during the manufacturing process of the touch sensor TS.

Accordingly, the touch buffer film T-BUF may prevent damage to the emission layer EL that is vulnerable to liquid or moisture.

The touch buffer film T-BUF may be formed at a low temperature (e.g., 100° C.) or lower, and may be formed of an organic insulating material having a low dielectric constant in order to prevent damage to the emission layer EL including an organic material vulnerable to high temperatures. For example, the touch buffer film T-BUF may be formed of an acrylic series, an epoxy series, or a siloxane series material.

If the display device 100 is bent, the encapsulation layer ENCAP may be damaged due to bending, and the touch sensor metal TSM located on the touch buffer film T-BUF may be broken. Even if the display device 100 is bent, the encapsulation layer ENCAP may be prevented from being damaged or the touch sensor metal TSM or bridge metal BRG may be prevented from being broken by the touch buffer film T-BUF having flattening performance using an organic insulating material.

A protection layer PAC can be arranged while covering the touch sensor TS. The protection layer PAC can be, for example, an organic insulating film. Specifically, the protection layer PAC may be configured to cover the touch sensor TS and the touch interlayer insulating film T-ILD.

In the display area DA, light emitting element ED emitting light of different colors may correspond to subpixels SP, and a plurality of light emitting elements ED may be disposed so as not to overlap depending on the color of light emitted.

In contrast, in the display device 100 of the present disclosure, when forming an optical emission area OEA in the optical area OA where the optical electronic device 11 is disposed, a pixel may be formed so that subpixels of different colors (e.g., red subpixels, green subpixels, and blue subpixels) overlap with each other. Accordingly, it is possible to increase the area of the transmission area TA, and improve the transmittance of the optical area OA.

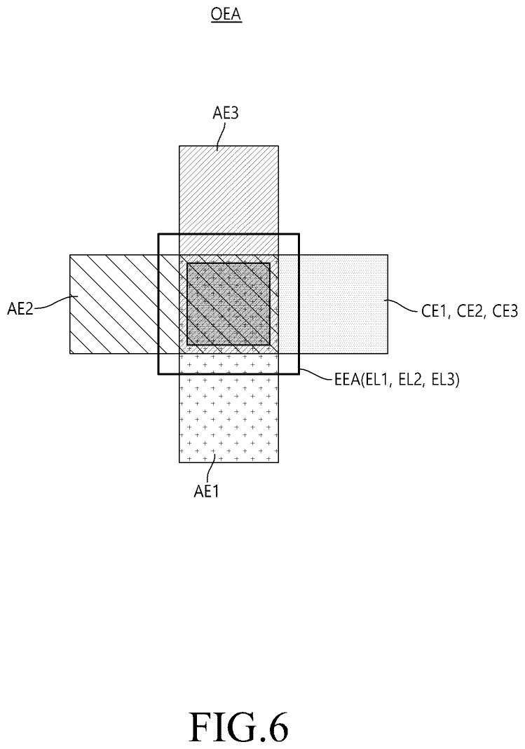

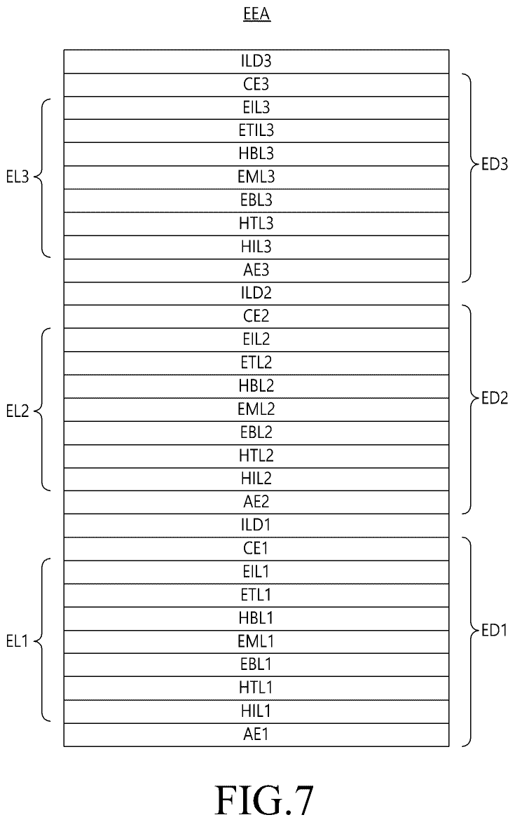

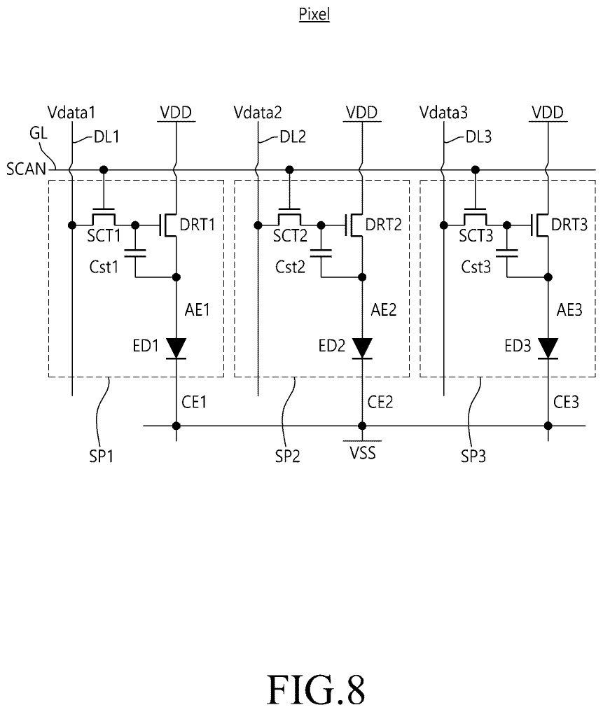

FIG. 6 illustrates an exemplary plane of an optical emission area formed in an optical area in a display device according to exemplary embodiments of the present disclosure, FIG. 7 illustrates an exemplary cross-section of an optical emission area formed in an optical area in a display device according to exemplary embodiments of the present disclosure, and FIG. 8 illustrates an exemplary circuit of a subpixel formed in an optical area in a display device according to exemplary embodiments of the present disclosure.

First, referring to FIG. 6, in the display device 100 according to the exemplary embodiments of the present disclosure, the optical area OA may include an optical emission area OEA and a transmission area TA.

The optical emission area OEA may correspond to an area in which a subpixel is formed within the optical area OA.

For example, the optical emission area OEA may comprise a pixel in which a plurality of subpixels of different colors are stacked, and the plurality of subpixels may emit light at different times.

The optical emission area OEA may include an overlapping emission area EEA in which a first light emitting element constituting a red subpixel, a second light emitting element constituting a green subpixel, and a third light emitting element constituting a blue subpixel overlap.

The first light emitting element may include a first anode electrode AE1, a first emission layer EL1, and a first cathode electrode CE1, the second light emitting element may include a second anode electrode AE2, a second emission layer EL2, and a second cathode electrode CE2, and the third light emitting element may include a third anode electrode AE3, a third emission layer EL3, and a third cathode electrode CE3.

In this case, the first emission layer EL1, the second emission layer EL2, and the third emission layer EL3 may be disposed to overlap with each other in an overlapping emission area EEA.

Meanwhile, the first anode electrode AE1, the second anode electrode AE2, and the third anode electrode AE3 may be disposed to overlap with each other in the overlapping emission area EEA, but may be formed to extend in different directions from the overlapping emission area EEA to an outer side of the overlapping emission area EEA.

As one example, the first anode electrode AE1, the second anode electrode AE2, the third anode electrode AE3 may be formed to extend in different directions from the first cathode electrode CE1, the second cathode electrode CE2, and the third cathode electrode CE3, but is not limited thereto.

For example, the first anode electrode AE1 may extend downward from the overlapping emission area EEA, the second anode electrode AE2 may extend leftward from the overlapping emission area EEA, and the third anode electrode AE3 may extend upward from the overlapping emission area EEA.

In addition, the first cathode electrode CE1, the second cathode electrode CE2, and the third cathode electrode CE3 may be disposed to overlap with each other in the overlapping emission area EEA, and may extend in the same direction from the overlapping emission area EEA and be electrically connected at the outside of the overlapping emission area EEA.

For example, the first cathode electrode CE1, the second cathode electrode CE2, and the third cathode electrode CE3 may extend in an opposite direction to the second anode electrode AE2, but is not limited thereto.

For example, the first cathode electrode CE1, the second cathode electrode CE2, and the third cathode electrode CE3 may extend in the right direction from the overlapping emission area EEA and be electrically connected to a pixel low-potential voltage line.

Therefore, the overlapping emission area EEA may be formed in the central portion of the anode electrodes AE1, AE2 and AE3 and the cathode electrodes CE1, CE2 and CE3.

Referring to FIG. 7, in a display device according to exemplary embodiments of the present disclosure, an optical emission area OEA may be stacked such that a first light emitting element ED1, a second light emitting element ED2, and a third light emitting element ED3 overlap with each other.

As one example, the first light emitting element ED1 may include a first anode electrode, a first emission layer, and a first cathode electrode sequentially stacked.

The first light emitting element ED1 may include a first emission layer EL1, and a first anode electrode AE1 and a first cathode electrode CE1 facing each other with the first emission layer EL1 interposed therebetween.

The first emission layer EL1 includes a first emission material layer EML1, and may further include a first hole injection layer HIL1, a first hole transport layer HTL1, a first electron blocking layer EBL1, a first hole blocking layer HBL1, a first electron transport layer ETL1, and a first electron injection layer EIL1.

Here, in the first emission layer EL1, the first electron blocking layer EBL1 and the first hole blocking layer HBL1 may be omitted.

The first light emitting element ED1 may form excitons during an excitation process when holes injected into the first anode electrode AE1 and electrons injected into the first cathode electrode CE1 recombine in the first emission material layer EML1, and may emit light by energy from the excitons.

The first anode electrode AE1 may be formed of a conductive material having a relatively large work function value. For example, the first anode electrode AE may be formed of ITO, IZO, ITZO, SnO, ZnO, ICO, AZO, and/or a combination thereof.

The first hole injection layer HIL1 may be positioned between the first anode electrode AE1 and the first hole transport layer HTL1, and may improve the interface characteristics between the first anode electrode AE1 and the first hole transport layer HTL1. For example, the first hole injection layer HIL1 may include MTDATA, NATA, 1TNATA, 2T-NATA, CuPc, TCTA, NPB(NPD), DNTPD, HAT-CN, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB, MgF2, CaF2, and/or a combination thereof.

The first hole transport layer HTL1 may supply holes to the first emission material layer EML1. The first hole transport layer HTL1 may each include TPD, NPB, DNTPD, BPBPA, CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl)-4-amine, N-([1,1′-biphenyl]-4-yl)-9,9-dimethyl-N-(4-(9-phenyl-9H-carbazol-3-yl)phenyl)-9H-fluoren-2-amine and/or a combination thereof.

The first electron blocking layer EBL1 may improve the coupling of holes and electrons in the first emission material layer EML1 and enhance the luminescence efficiency of the first emission material layer EML1 by preventing electrons injected into the first emission material layer EML1 from passing to the first hole transport layer HTL1.

As one example, the first emission material layer EML1 may emit a light of first color, and may include a first emission material layer among a red emission material layer, a green emission material layer, and a blue emission material layer, but is not limited thereto.

The first emission material layer EML1 may include a red emission material layer that emits red light among a red emission material layer, a green emission material layer, and a blue emission material layer, but is not limited thereto.

Alternatively, the first emission material layer EML1 may include any one of a cyan emission material layer, a magenta emission material layer and a yellow emission material layer, but is not limited thereto.

The first hole blocking layer HBL1 may improve the coupling of holes and electrons in the first emission material layer EML1 and enhance the luminescence efficiency of the first emission material layer EML1 by preventing holes injected into the first emission material layer EML1 from passing to the first electron transport layer ETL1.

The first electron transport layer ETL1 may supply electrons to the first emission material layer EML1. The first electron transport layer ETL1 may include any one of an oxadiazole-based compound, a triazole-based compound, a phenanthroline-based compound, a benzoxazole-based compound, a benzothiazole-based compound, a benzimidazole-based compound, and a triazine-based compound.

The first electron injection layer EIL1 may be located between the first cathode electrode CE1 and the first electron transport layer ETL1 and improve the characteristics of the first cathode electrode CE1 and the lifespan of the first light emitting element ED1. The first electron injection layer EIL1 may use an alkali metal halide-based material such as LiF, CsF, NaF, or BaF2, and/or an alkaline earth metal halide-based material, and/or an organometallic material such as Liq, lithium benzoate, or sodium stearate.

In this case, in order to increase the luminescence efficiency of the first light emitting element ED1, the first electron injection layer EIL1 may include a film structure of ytterbium (Yb) and lithium fluoride (LiF).

The first cathode electrode CE1 may be located on the front surface of the display area DA, and may be formed of a material having a relatively low work function value. For example, the first cathode electrode CE1 may be made of aluminum (Al), magnesium (Mg), calcium (ca), silver (Ag), an alloy thereof, and/or a combination thereof (for example, a material having good reflective properties such as an aluminum-magnesium alloy (AlMg)).

As one example, the first light emitting element ED1 may be a first light emitting element that emits the first light.

The first light emitting element ED1 may be a red light emitting element that emits red light, but is not limited thereto.

A first interlayer insulating film ILD1 may be disposed between the first light emitting element ED1 and the second light emitting element ED2.

The first interlayer insulating film ILD1 may include aluminum oxide (Al2O3).

As one example, the second light emitting element ED2 may include a second anode electrode, a second emission layer, and a second cathode electrode sequentially stacked.

The second light emitting element ED2 may include a second emission layer EL2, and a second anode electrode AE2 and a second cathode electrode CE2 that face each other with the second emission layer EL2 interposed therebetween.

The second emission layer EL2 may include a second emission material layer EML2, and may further include a second hole injection layer HIL2, a second hole transport layer HTL2, a second electron blocking layer EBL2, a second hole blocking layer HBL2, a second electron transport layer ETL2, and a second electron injection layer EIL2.

Here, in the second emission layer EL2, the second electron blocking layer EBL2 and the second hole blocking layer HBL2 may be omitted.

The second light emitting element ED2 may form excitons during the excitation process when holes injected into the second anode electrode AE2 and electrons injected into the second cathode electrode CE2 recombine in the second emission material layer EML2, and may emit light by energy from the excitons.

The second hole injection layer HIL2 may be located between the second anode electrode AE2 and the second hole transport layer HTL2, and may improve the interface characteristics between the second anode electrode AE2 and the second hole transport layer HTL2.

The second hole transport layer HTL2 may supply holes to the second emission material layer EML2.

The second electron blocking layer EBL2 may improve the coupling of holes and electrons in the second emission material layer EML2 and enhance the luminescence efficiency of the second emission material layer EML2 by preventing electrons injected into the second emission material layer EML2 from passing to the second hole transport layer HTL2.

As one example, the second emission material layer EML2 may emit a light of second color, and may include a second emission material layer among a red emission material layer, a green emission material layer, and a blue emission material layer, but is not limited thereto.

The second emission material layer EML2 may include a green emission material layer that emits green light among a red emission material layer, a green emission material layer, and a blue emission material layer, but is not limited thereto.

Alternatively, the second emission material layer EML2 may include any one of a cyan emission material layer, a magenta emission material layer and a yellow emission material layer, but is not limited thereto.

The second hole blocking layer HBL2 can improve the coupling of holes and electrons in the second emission material layer EML2 and enhance the luminescence efficiency of the second emission material layer EML2 by preventing holes injected into the second emission material layer EML2 from passing to the second electron transport layer ETL2.

The second electron transport layer ETL2 may supply electrons to the second emission material layer EML2.

The second electron injection layer EIL2 can be located between the second cathode electrode CE2 and the second electron transport layer ETL2, and improve the characteristics of the second cathode electrode CE2 and the lifespan of the second light emitting element ED2.

In this case, in order to increase the luminescence efficiency of the second light emitting element ED2, the second electron injection layer EIL2 may include a film structure of ytterbium (Yb) and lithium fluoride (LiF).

The second cathode electrode CE2 may be located on the entire surface of the display area DA, and may be formed of a material having a relatively low work function value.

As one example, the second light emitting element ED2 may be a second light emitting element that emits the second light.

The second light emitting element ED2 may be a green light emitting element that emits green light.

A second interlayer insulating film ILD2 may be disposed between the second light emitting element ED2 and the third light emitting element ED3.

The second interlayer insulating film ILD2 may include aluminum oxide (Al2O3) or gallium oxide.

As one example, the third light emitting element ED3 may include a third anode electrode, a third emission layer, and a third cathode electrode sequentially stacked.

The third light emitting element ED3 may include a third emission layer EL3 and a third anode electrode AE3 and a third cathode electrode CE3 that face each other with the third emission layer EL3 interposed therebetween.

The third emission layer EL3 may include a third emission material layer EML3, and may further include a third hole injection layer HIL3, a third hole transport layer HTL3, a third electron blocking layer EBL3, a third hole blocking layer HBL3, a third electron transport layer ETL3, and a third electron injection layer EIL3.

Here, the third electron blocking layer EBL3 and the third hole blocking layer HBL3 may be omitted in the third emission layer EL3.

The third light emitting element ED3 may form excitons during the excitation process when holes injected into the third anode electrode AE3 and electrons injected into the third cathode electrode CE3 recombine in the third emission material layer EML3, and may emit light by energy from the excitons.

The third hole injection layer HIL3 may be located between the third anode electrode AE3 and the third hole transport layer HTL3, and may improve the interface characteristics between the third anode electrode AE3 and the third hole transport layer HTL3.

The third hole transport layer HTL3 may supply holes to the third emission material layer EML3.

The third electron blocking layer EBL3 can improve the coupling of holes and electrons in the third emission material layer EML3 and enhance the luminescence efficiency of the third emission material layer EML3 by preventing electrons injected into the third emission material layer EML3 from passing to the third hole transport layer HTL3.

As one example, the third emission material layer EML3 may emit a light of third color, and may include a third emission material layer among a red emission material layer, a green emission material layer, and a blue emission material layer, but is not limited thereto.

The third emission material layer EML3 can include a blue emission material layer among the red emission material layer, the green emission material layer, and the blue emission material layer, but is not limited thereto.

Alternatively, the third emission material layer EML3 may include any one of a cyan emission material layer, a magenta emission material layer and a yellow emission material layer, but is not limited thereto.

The third hole blocking layer HBL3 can improve the coupling of holes and electrons in the third emission material layer EML3 and enhance the luminescence efficiency of the third emission material layer EML3 by preventing holes injected into the third emission material layer EML3 from passing to the third electron transport layer ETL3.

The third electron transport layer ETL3 may supply electrons to the third emission material layer EML3.

The third electron injection layer EIL3 can be located between the third cathode electrode CE3 and the third electron transport layer ETL3, and improve the characteristics of the third cathode electrode CE3 and the lifespan of the third light emitting element ED3.

In this case, in order to increase the luminescence efficiency of the third light emitting element ED3, the third electron injection layer EIL3 may include a film structure of ytterbium (Yb) and lithium fluoride (LiF).

The third cathode electrode CE3 may be located on the entire surface of the display area DA, and may be formed of a material having a relatively low work function value.

As one example, the third light emitting element ED3 may be a third light emitting element that emits the third light.

The third light emitting element ED3 may be a blue light emitting element that emits blue light.

A third interlayer insulating film ILD3 may be arranged on the upper portion of the third light emitting element ED3.

The third interlayer insulating film ILD3 may include aluminum oxide (Al₂O₃) or gallium oxide.

Referring to FIG. 8, in the display device 100 of the present disclosure, one pixel may include three subpixels SP1, SP2 and SP3. In this case, a first subpixel SP1 may be a red subpixel, a second subpixel SP2 may be a green subpixel, and a third subpixel SP3 may be a blue subpixel. Meanwhile, one pixel may be composed of four subpixels that further include a white subpixel.

Each subpixel SP may include a light emitting element ED and a subpixel circuit. That is, the remaining circuits in the subpixel SP excluding the light emitting element ED may be referred to as a subpixel circuit.

In this case, the subpixel circuit constituting the subpixel may be configured in various ways, and here, a case in which the subpixel circuit of FIG. 3 is configured is illustrated as an example.

The first to third subpixels SP1, SP2 and SP3 may include the first to third light emitting elements ED1, ED2 and ED3, respectively. For example, the first to third subpixels SP1, SP2 and SP3 may include the first to third light emitting elements ED1, ED2 and ED3 which emit the light of different colors.

For example, the first cathode electrode CE1, the second cathode electrode CE2, and the third cathode electrode CE3 constituting the first to third light emitting elements ED1, ED2 and ED3 may be commonly connected to a pixel low-potential voltage line to which a pixel low-potential voltage VSS is supplied. In this case, the first cathode electrode CE1, the second cathode electrode CE2, and the third cathode electrode CE3 may be supplied with the same pixel low-potential voltage VSS.

Meanwhile, the first anode electrode AE1, the second anode electrode AE2, and the third anode electrode AE3 constituting the first to third light emitting elements ED1, ED2 and ED3 may be electrically insulated, and the first data voltage Vdata1 to the third data voltage Vdata3 may be supplied through a first data line DL1 to a third data line DL3.

Therefore, even if the first light emitting element ED1 of red color, the second light emitting element ED2 of green color, and the third light emitting element ED3 of blue color overlap with each other in the overlapping emission area EEA, the first anode electrode AE1, the second anode electrode AE2, and the third anode electrode AE3 may be independently controlled at different times to control an emission of a desired color.

Meanwhile, the display device 100 of the present disclosure can increase the transmittance of the optical area OA while simplifying the vertical stacking structure by sharing a part of anode electrodes and a part of cathode electrodes for different color subpixels (e.g., red subpixels, green subpixels, and blue subpixels) that are disposed to overlap with each other.

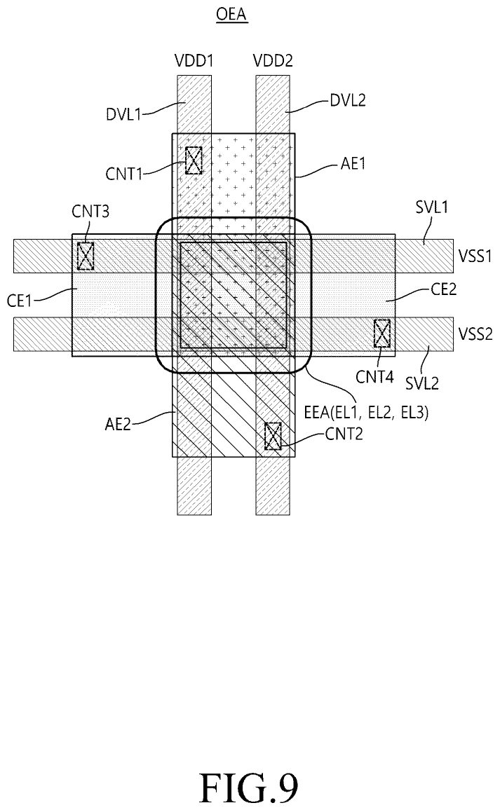

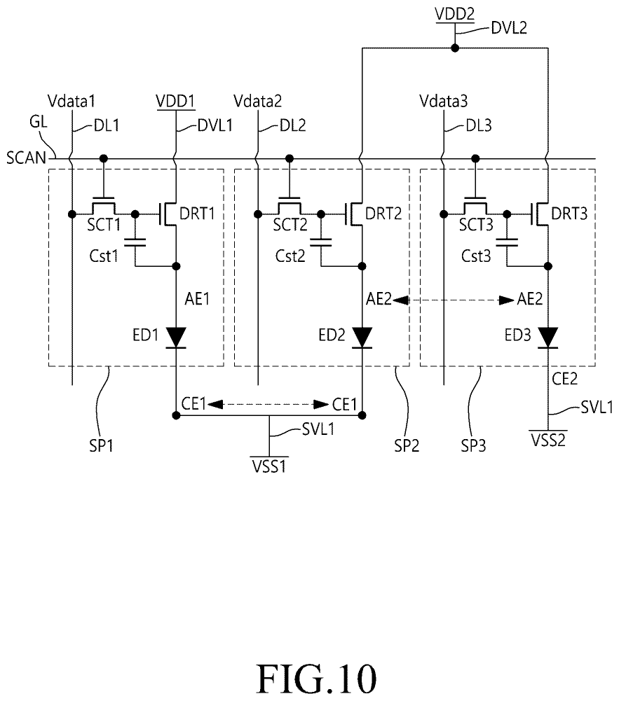

FIG. 9 illustrates an example of a plane of an optical emission area formed in an optical area in a display device according to other embodiments of the present disclosure, and FIG. 10 illustrates an example of a circuit of a subpixel formed in an optical area in a display device according to other embodiments of the present disclosure.

First, referring to FIG. 9 and FIG. 10, in the display device 100 according to other embodiments of the present disclosure, the optical area OA may include an optical emission area OEA and a transmission area TA.

The optical emission area OEA may be an area in which a pixel including the first subpixel SP1 to the third subpixel SP3 is formed within the optical area OA.

The optical emission area OEA may include an overlapping emission area EEA in which the first light emitting element ED1 constituting the first subpixel SP1, the second light emitting element ED2 constituting the second subpixel SP2, and the third light emitting element ED3 constituting the third subpixel SP3 overlap with each other.

The first light emitting element ED1 to the third light emitting element ED3 may each include an anode electrode, an emission layer, and a cathode electrode.

In this case, a first emission layer EL1 of the first light emitting element ED1, a second emission layer EL2 of the second light emitting element ED2, and a third emission layer EL3 of the third light emitting element ED3 may be disposed to overlap in an overlapping emission area EEA.

For example, the each of the first emission layer EL1 to the third emission layer EL3 may include a hole injection layer, a hole transport layer, an electron blocking layer, a emission material layer, a hole blocking layer, an electron transport layer, and an electron injection layer, but is not limited thereto.

Meanwhile, the display device 100 of the present disclosure can simplify the stacking structure of overlapping subpixels by forming two light emitting elements to share one anode electrode and two other light emitting elements to share one cathode electrode.

For example, a cathode electrode of the first light emitting element ED1 and a cathode electrode of the second light emitting element ED2 may be shared, and an anode electrode of the second light emitting element ED2 and an anode electrode of the third light emitting element ED3 may be shared.

In this case, the first light emitting element ED1 and the second light emitting element ED2 sharing the cathode electrode may be referred to as a first group light emitting element, and the second light emitting element ED2 and the third light emitting element ED3 sharing the anode electrode may be referred to as a second group light emitting element. In addition, the first subpixel SP1 and the second subpixel SP2 sharing the cathode electrode may be referred to as a first group subpixel, and the second subpixel SP2 and the third subpixel SP3 sharing the anode electrode may be referred to as a second group subpixel.

Accordingly, two anode electrodes AE1 and AE2 and two cathode electrodes CE1 and CE2 may be disposed in the optical emission area OEA to control the first light emitting element ED1 to the third light emitting element ED3.

Meanwhile, in order to independently control the first group light emitting elements ED1 and ED2 and the second group light emitting elements ED2 and ED3, two pixel high-potential voltage lines DVL1 and DVL2 supplied with different pixel high-potential voltages VDD1 and VDD2 and two pixel low-potential voltage lines SVL1 and SVL2 supplied with different pixel low-potential voltages VSS1 and VSS2 may be arranged.

In this case, for efficient arrangement of the optical emission area OEA, the first anode electrode AE1 and the second anode electrode AE2 may be arranged in a direction parallel to the direction of the extension of the pixel high-potential voltage lines DVL1 and DVL2.

In this case, the first anode electrode AE1 and the second anode electrode AE2 may be electrically connected to a lower source-drain electrode pattern SD1 and SD2 through a first contact hole CNT1 and a second contact hole CNT2, respectively, and may be electrically connected to a source electrode of the corresponding driving transistor DRT.

Since the first cathode electrode CE1 and the second cathode electrode CE2 are supplied with the pixel low-potential voltage VSS1 and VSS2, the first cathode electrode CE1 and the second cathode electrode CE2 may be arranged in a direction parallel to the extension direction of the pixel low-potential voltage lines SVL1 and SVL2.

In this case, the first cathode electrode CE1 may be electrically connected to the pixel low-potential voltage line SVL1 through a third contact hole CNT3 and the second cathode electrode CE2 may be electrically connected to the pixel low-potential voltage line SVL2 through a fourth contact hole CNT4.

Meanwhile, the first anode electrode AE1 and the second anode electrode AE2 may be arranged to overlap with each other in the overlapping emission area EEA, but may be formed to extend in different directions from the overlapping emission area EEA to the outer side of the overlapping emission area EEA.

For example, the first anode electrode AE1 may extend upward from the overlapping emission area EEA, and the second anode electrode AE2 extend in an opposite direction to the first anode electrode AE1.

In addition, the first cathode electrode CE1 and the second cathode electrode CE2 may be arranged to overlap with each other in the overlapping emission area EEA, but may be formed to extend in different directions from the overlapping emission area EEA to the outer side of the overlapping emission area EEA.

For example, the first cathode electrode CE1 may extend leftward from the overlapping emission area EEA, and the second cathode electrode CE2 extend in an opposite direction to the first anode electrode AE1.

Therefore, the overlapping emission area EEA may be formed in the central portion of the anode electrode AE1 and AE2, and the cathode electrode CE1 and CE2.

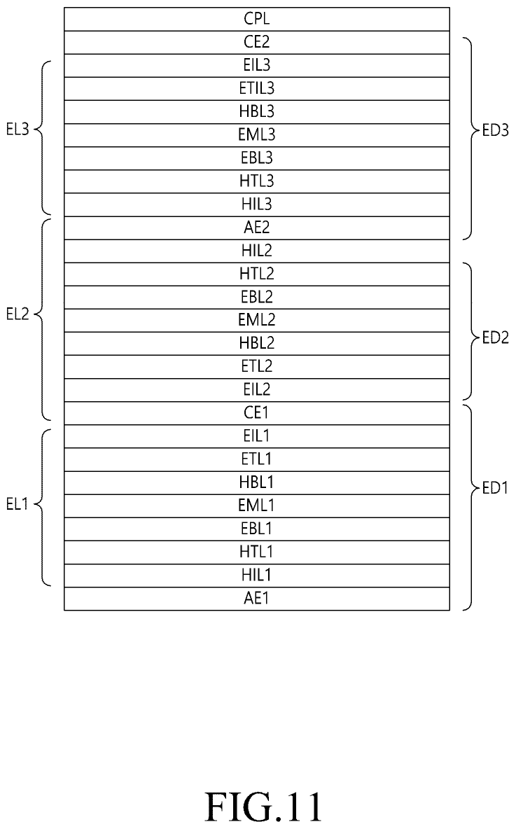

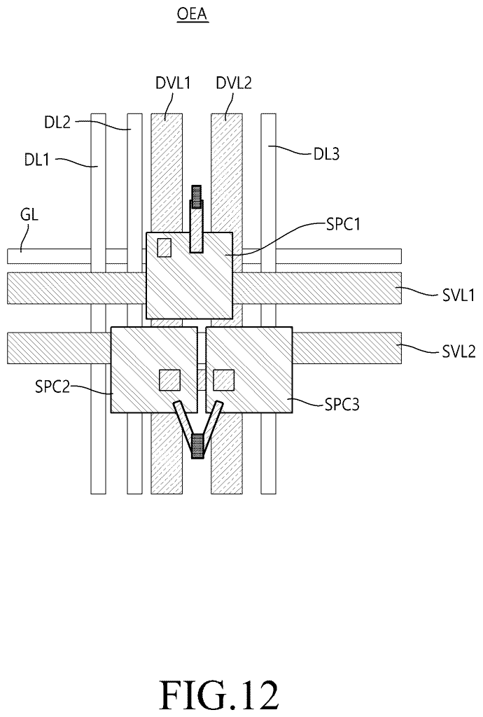

FIG. 11 illustrates an exemplary cross-section of an optical emission area formed in an optical area in a display device according to further exemplary embodiments of the present disclosure. In addition, FIGS. 12 to 19 are plan views illustrating a manufacturing process of an optical emission area formed in an optical area in a display device according to another embodiments of the present disclosure.

First, referring to FIG. 12, in the optical emission area OEA of the display device 100 according to another embodiments of the present disclosure, there may be formed a gate line transmitting a scan signal to the first to third subpixels, and a data line DL1, DL2 and DL3 transmitting a data voltage to the first to third subpixels, respectively.

In addition, a first pixel high-potential voltage line DVL1 supplying a first pixel high-potential voltage VDD1 and a second pixel high-potential voltage line DVL2 supplying a second pixel high-potential voltage VDD2 may be formed in a first direction in the optical emission area OEA.

The first pixel high-potential voltage VDD1 may be supplied to the first light emitting element ED1. The second pixel high-potential voltage VDD2 may be commonly supplied to the second light emitting element ED2 and the third light emitting element ED3.

For example, the first pixel high-potential voltage VDD1 may be supplied to the first subpixel. The second pixel high-potential voltage VDD2 may be commonly supplied to the second subpixel and the third subpixel.

In addition, a first pixel low-potential voltage line SVL1 supplying the first pixel low-potential voltage VSS1 and a second pixel low-potential voltage line SVL2 supplying the second pixel low-potential voltage VSS2 may be formed in a second direction in the optical emission area OEA.

The first pixel low-potential voltage VSS1 may be commonly supplied to the first light emitting element ED1 and the second light emitting element ED2. In addition, the second pixel low-potential voltage VSS2 may be supplied to the third light emitting element ED3.

A first subpixel circuit SPC1 driving the first light emitting element ED1, a second subpixel circuit SPC2 driving the second light emitting element ED2, and a third subpixel circuit SPC3 driving the third light emitting element ED3 may be formed in the optical emission area OEA.

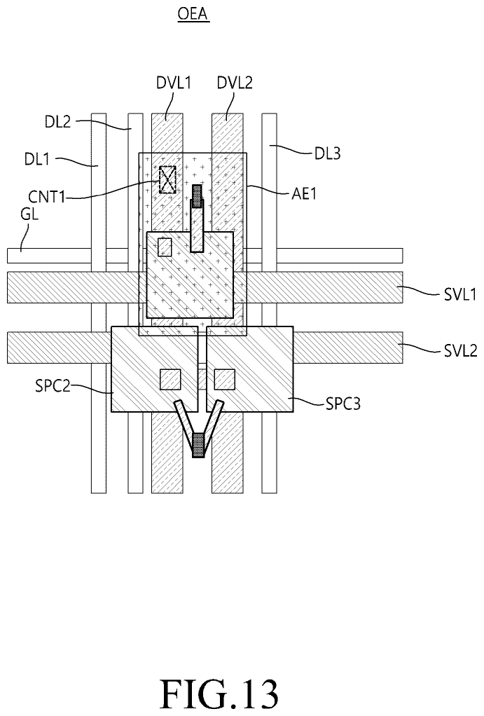

Referring to FIG. 11 and FIG. 13, the first anode electrode AE1 may be formed in a direction parallel to the pixel high-potential voltage lines DVL1 and DVL2.

The first anode electrode AE1 may be formed of a conductive material having a relatively large work function value.

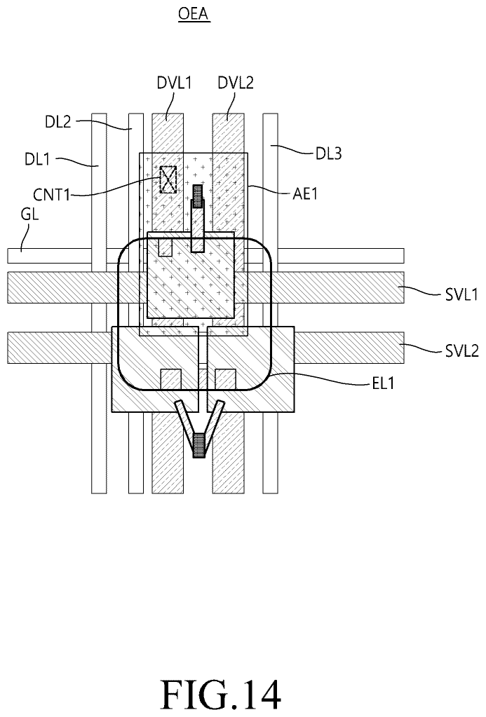

Referring to FIG. 11 and FIG. 14, the first light emitting element ED1 may include a first emission layer EL1 positioned on the first anode electrode AE1 to overlap with at least a portion of the first anode electrode AE1.

The first emission layer EL1 may include a first emission material layer EML1, and may further include a first hole injection layer HIL1, a first hole transport layer HTL1, a first electron blocking layer EBL1, a first hole blocking layer HBL1, a first electron transport layer ETL1, and a first electron injection layer EIL1.

For example, the first emission layer may include a first hole injection layer HIL1, a first hole transport layer HTL1, a first electron blocking layer EBL1, the first emission material layer EML1, a first hole blocking layer HBL1, a first electron transport layer ETL1, and a first electron injection layer EIL1 sequentially stacked, but is not limited thereto.

Here, the first electron blocking layer EBL1 and the first hole blocking layer HBL1 may be omitted in the first emission layer EL1.

The first light emitting element ED1 may form excitons in the excitation process when holes injected into the first anode electrode AE1 and electrons injected into the first cathode electrode CE1 recombine in the first emission material layer EML1, and may emit light by energy from the excitons.

The first hole injection layer HIL1 may be located between the first anode electrode AE1 and the first hole transport layer HTL1, and can improve the interface characteristics between the first anode electrode AE1 and the first hole transport layer HTL1.

The first hole transport layer HTL1 may supply holes to the first emission material layer EML1.

The first electron blocking layer EBL1 may prevent electrons injected into the first emission material layer EML1 from passing to the first hole transport layer HTL1, thereby improving the coupling of holes and electrons in the first emission material layer EML1 and improving the luminescence efficiency of the first emission material layer EML1.

The first emission material layer EML1 may include a red emission material layer that emits red light among a red emission material layer, a green emission material layer, and a blue emission material layer, but is not limited thereto.

The first hole blocking layer HBL1 can improve the coupling of holes and electrons in the first emission material layer EML1 by preventing holes injected into the first emission material layer EML1 from passing to the first electron transport layer ETL1, thereby improving the luminescence efficiency of the first emission material layer EML1.

The first electron transport layer ETL1 may supply electrons to the first emission material layer EML1.

The first electron injection layer EIL1 may be located between the first cathode electrode CE1 and the first electron transport layer ETL1, and improve the characteristics of the first cathode electrode CE1 and the lifespan of the first light emitting element ED1.

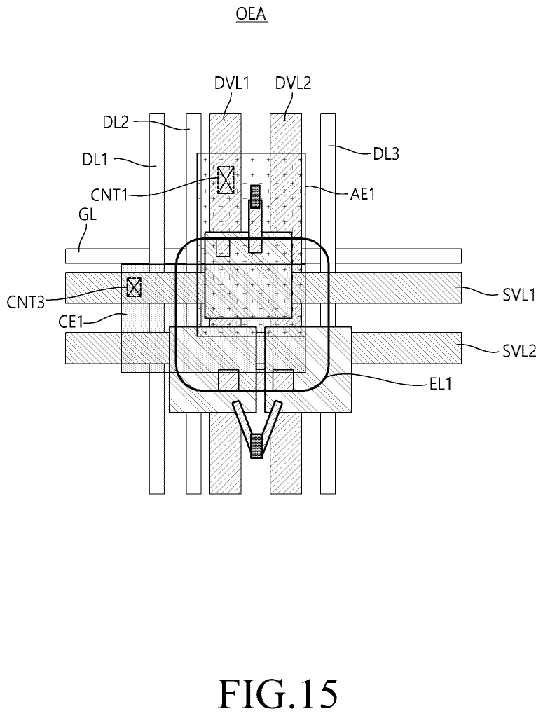

Referring to FIG. 11 and FIG. 15, the first cathode electrode CE1 may be formed to overlap with a portion of the first emission layer EL1 and extend in a direction parallel to the pixel low-potential voltage lines SVL1 and SVL2.

The first cathode electrode CE1 may be formed of a material having a relatively low work function value.

In this case, a cathode electrode of the second light emitting element ED2 may share the first cathode electrode CE1 of the first light emitting element ED1. That is, the first cathode electrode CE1 may operate as a cathode electrode of the first light emitting element ED1 above the first light emitting element ED1 and may operate as a cathode electrode of the second light emitting element ED2 below the second light emitting element ED2.

In this case, the first light emitting element ED1 and the second light emitting element ED2 may have opposite directions of electron and hole progression. Therefore, the arrangement of the first emission layer EL1 constituting the first light emitting element ED1 and the second emission layer EL2 constituting the second light emitting element ED2 may be symmetrical with respect to the first cathode electrode CE1.

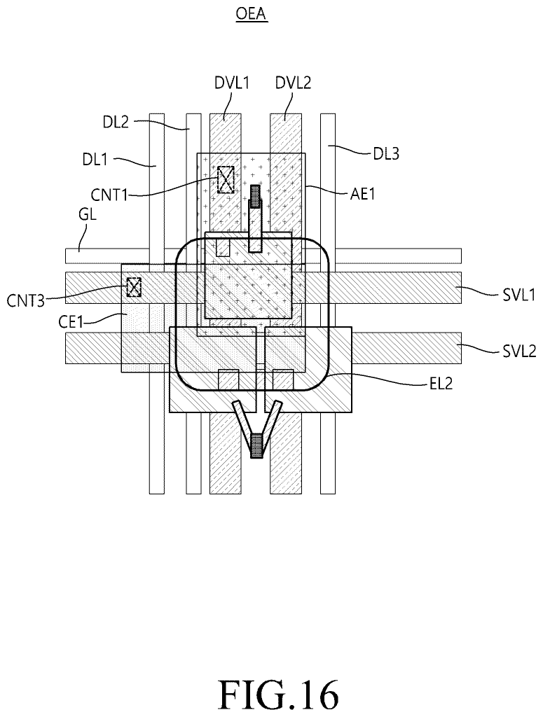

Referring to FIG. 11 and FIG. 16, the second light emitting element ED2 may include a second emission layer EL2 located on the first cathode electrode CE1 so as to overlap with at least a portion of the first cathode electrode CE1.

The second emission layer EL2 may include a second emission material layer EML2, and may further include a second electron injection layer EIL2, a second electron transport layer ETL2, a second hole blocking layer HBL2, a second electron blocking layer EBL2, a second hole transport layer HTL2, and a second hole injection layer HIL2.

For example, the second emission layer EL2 may include a second electron injection layer EIL2, a second electron transport layer ETL2, a second hole blocking layer HBL2, a second emission material layer EML2, a second electron blocking layer EBL2, a second hole transport layer HTL2, and a second hole injection layer HIL2 sequentially stacked, but is not limited thereto.

The second electron blocking layer EBL2 and the second hole blocking layer HBL2 may be omitted in the second emission layer EL2.

The second light emitting element ED2 may form excitons in an excitation process when holes injected into the second anode electrode AE2 and electrons injected into the second cathode electrode CE2 recombine in the second emission material layer EML2, and may emit light by energy from the excitons.

The second electron injection layer EIL2 can improve the characteristics of the second cathode electrode CE2 and the lifespan of the second light emitting element ED2 between the second cathode electrode CE2 and the second electron transport layer ETL2.

The second electron transport layer ETL2 may supply electrons to the second emission material layer EML2.

The second hole blocking layer HBL2 can improve the coupling of holes and electrons in the second emission material layer EML2 and improve the luminescence efficiency of the second emission material layer EML2 by preventing holes injected into the second emission material layer EML2 from passing to the second electron transport layer ETL2.

The second emission material layer EML2 may include a green emission material layer that emits green light among a red emission material layer, a green emission material layer, and a blue emission material layer, but is not limited thereto.

The second electron blocking layer EBL2 can improve the coupling of holes and electrons in the second emission material layer EML2 and enhance the luminescence efficiency of the second emission material layer EML2 by preventing electrons injected into the second emission material layer EML2 from passing to the second hole transport layer HTL2.

The second hole transport layer HTL2 may supply holes to the second emission material layer EML2.

The second hole injection layer HIL2 may be located between the second anode electrode AE2 and the second hole transport layer HTL2, and can enhance the interface characteristics between the second anode electrode AE2 and the second hole transport layer HTL2.

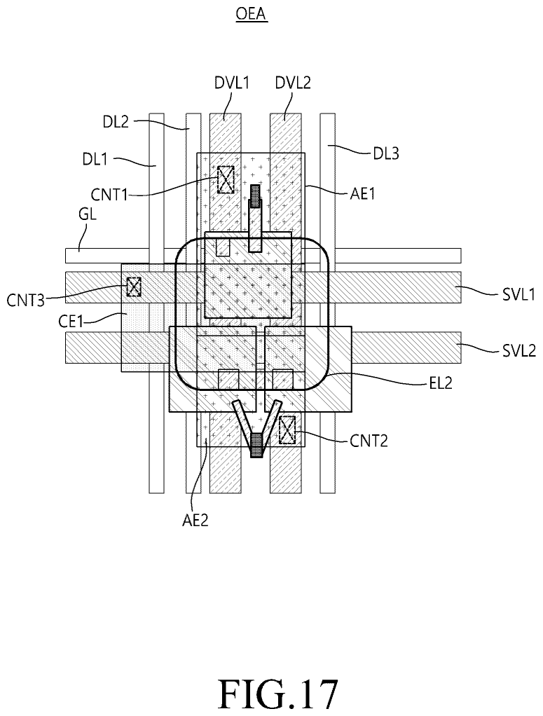

Referring to FIG. 11 and FIG. 17, the second anode electrode AE2 may be formed on the upper portion of the second emission layer EL2 to overlap with the second emission layer EL2 and extend in a direction parallel to the pixel high-potential voltage lines DVL1 and DVL2.

The second anode electrode AE2 may be formed of a conductive material having a relatively large work function value.

In this case, the third light emitting element ED3 and the second light emitting element ED2 may share the second anode electrode AE2. That is, the second anode electrode AE2 may operate as the anode electrode of the second light emitting element ED2, and, at the same time, may operate as the anode electrode of the third light emitting element ED3.

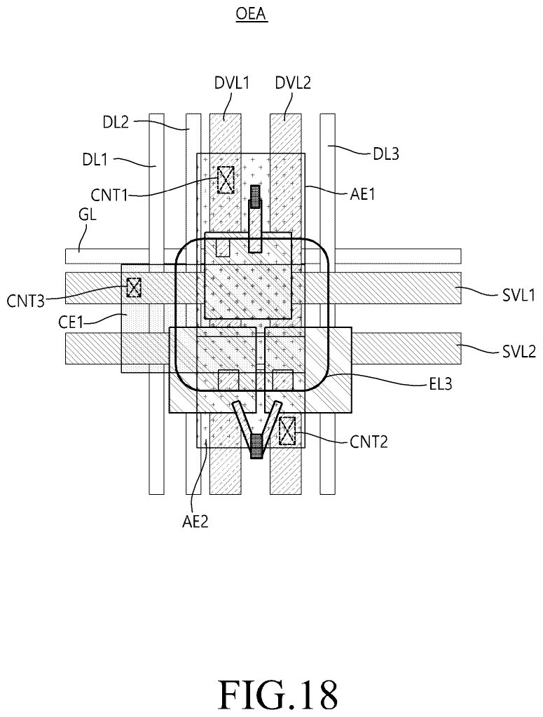

Referring to FIG. 11 and FIG. 18, the third light emitting element ED3 may include a third emission layer EL3 disposed to overlap with the second anode electrode AE2 on an upper portion of the second anode electrode AE2.

In this case, the second light emitting element ED2 and the third light emitting element ED3 may have opposite directions of electron and hole progression. Accordingly, the arrangement of the second emission layer EL2 constituting the second light emitting element ED2 and the third emission layer EL3 constituting the third light emitting element ED3 may be symmetrical with respect to the second anode electrode AE2.

The third emission layer EL3 may include a third emission material layer EML3, and may further include a third hole injection layer HIL3, a third hole transport layer HTL3, a third electron blocking layer EBL3, a third hole blocking layer HBL3, a third electron transport layer ETL3, and a third electron injection layer EIL3.

For example, the third emission layer EL3 may include a third hole injection layer HIL3, a third hole transport layer HTL3, a third electron blocking layer EBL3, a third emission material layer EML3, a third hole blocking layer HBL3, a third electron transport layer ETL3, and a third electron injection layer EIL3 sequentially stacked, but is not limited thereto.

Here, the third electron blocking layer EBL3 and the third hole blocking layer HBL3 of the third emission layer EL3 may be omitted.

The third light emitting element ED3 may form excitons in an excitation process when holes injected into the second anode electrode AE2 and electrons injected into the second cathode electrode CE2 recombine in the third emission material layer EML3, and may emit light by energy from the excitons.

The third hole injection layer HIL3 may be positioned between the second anode electrode AE2 and the third hole transport layer HTL3, and may improve the interface characteristics between the second anode electrode AE2 and the third hole transport layer HTL3.

The third hole transport layer HTL3 may supply holes to the third emission material layer EML3.

The third electron blocking layer EBL3 can improve the coupling of holes and electrons in the third emission material layer EML3 and improve the luminescence efficiency of the third emission material layer EML3 by preventing electrons injected into the third emission material layer EML3 from passing to the third hole transport layer HTL3.

The third emission material layer EML3 may include a blue emission material layer that emits blue light among a red emission material layer, a green emission material layer, and a blue emission material layer, but is not limited thereto.

The third hole blocking layer HBL3 can improve the coupling of holes and electrons in the third emission material layer EML3 by preventing holes injected into the third emission material layer EML3 from passing to the third electron transport layer ETL3, thereby improving the luminescence efficiency of the third emission material layer EML3.

The third electron transport layer ETL3 may supply electrons to the third emission material layer EML3.

The third electron injection layer EIL3 can improve the characteristics of the second cathode electrode CE2 and the lifespan of the third light emitting element ED3 between the second cathode electrode CE2 and the third electron transport layer ETL3.

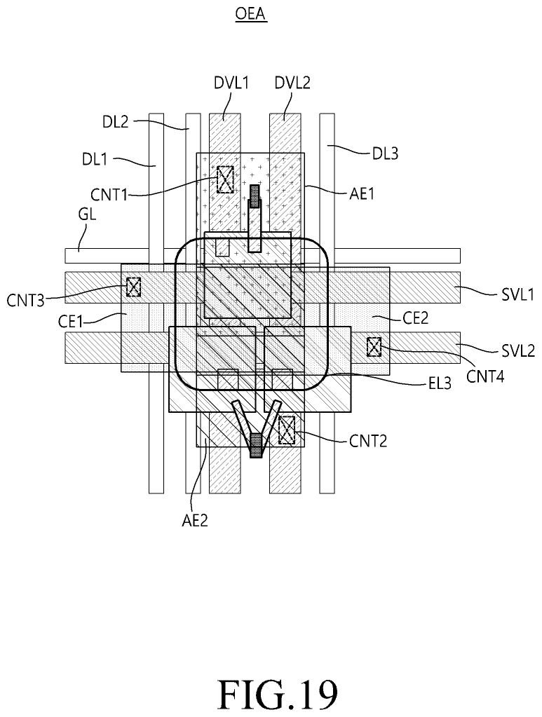

Referring to FIG. 11 and FIG. 19, a second cathode electrode CE2 may be formed on the upper portion of the third emission layer EL3 so as to overlap with the third emission layer EL3 and extend in a direction parallel to the pixel low-potential voltage lines SVL1 and SVL2.

The second cathode electrode CE2 may be formed of a material having a relatively low work function value.

Referring to FIG. 11, a capping layer CPL may be disposed on the upper portion of the second cathode electrode CE2 to improve light extraction and protect the light emitting elements ED1, ED2 and ED3. The capping layer CPL may be made of an organic material having a low molecular structure.

In this way, if the first light emitting element ED1 and the second light emitting element ED2 share the first cathode electrode CE1, and the second light emitting element ED2 and the third light emitting element ED3 share the second anode electrode AE2, three light emitting elements ED1, ED2 and ED3 may be configured with two anode electrodes AE1 and AE2 and two cathode electrodes CE1 and CE2, thereby simplifying the stacked structure and achieving process optimization.

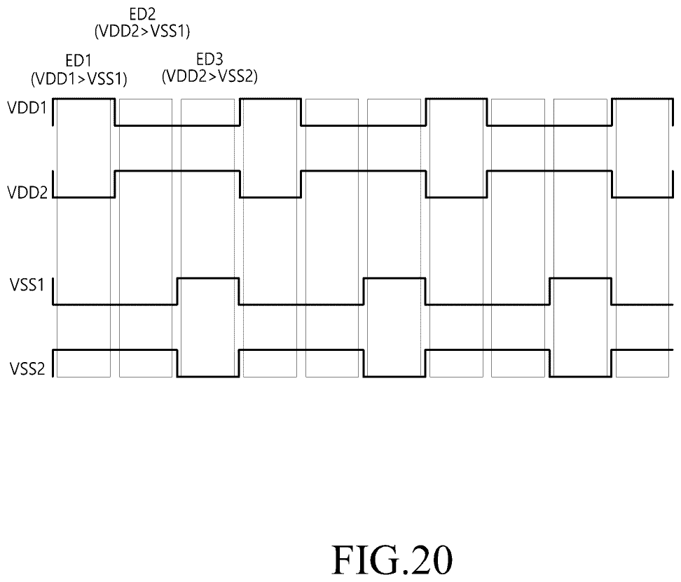

FIG. 20 illustrates an example of signal timing for time-division driving of the first to third light emitting elements of a stacked structure in a display device according to exemplary embodiments of the present disclosure.

Here, as shown in FIGS. 10 and 11, the first light emitting element ED1 and the second light emitting element ED2 may share the first cathode electrode CE1, and the second light emitting element ED2 and the third light emitting element ED3 may share the second anode electrode AE2.

Referring to FIG. 20, the display device 100 according to exemplary embodiments of the present disclosure may have a plurality of subpixels SP1, SP2 and SP3 that constitute one pixel in an optical emission area OEA arranged in a stacked structure.

In this case, the first light emitting element ED1 constituting the first subpixel SP1 and the second light emitting element ED2 constituting the second subpixel SP2 may share the first cathode electrode CE1, and the second light emitting element ED2 constituting the second subpixel SP2 and the third light emitting element ED3 constituting the third subpixel SP3 may share the second anode electrode AE2.

In this case, since the first pixel low-potential voltage line SVL1 is connected to the first cathode electrode CE1, the first pixel low-potential voltage VSS1 may be supplied to the first light emitting element ED1 and the second light emitting element ED2. In addition, since the second pixel high-potential voltage line DVL2 is connected to the second anode electrode AE2, the second light emitting element ED2 and the third light emitting element ED3 may be supplied with the second pixel high-potential voltage VDD2 together.

Therefore, if the first pixel high-potential voltage VDD1 is greater than the first pixel low-potential voltage VSS1, the first light emitting element ED1 can emit light. In addition, if the second pixel high-potential voltage VDD2 is greater than the first pixel low-potential voltage VSS1, the second light emitting element ED2 can emit light. In addition, if the second pixel high-potential voltage VDD2 is greater than the second pixel low-potential voltage VSS2, the third light emitting element ED3 can emit light.

Therefore, the display device 100 of the present disclosure may control the first light emitting element ED1, the second light emitting element ED2, and the third light emitting element ED3 to emit light at different times, even if the first light emitting element ED1, the second light emitting element ED2, and the third light emitting element ED3 of different colors are arranged to overlap with each other in the overlapping emission area EEA.

Meanwhile, in the display device 100 of the present disclosure, a plurality of subpixels may be disposed to overlap with each other in a pixel disposed in the optical area OA, however, a plurality of subpixels may also be disposed to overlap with each other in a pixel in the normal area NA where the optical electronic device 11 is not located.

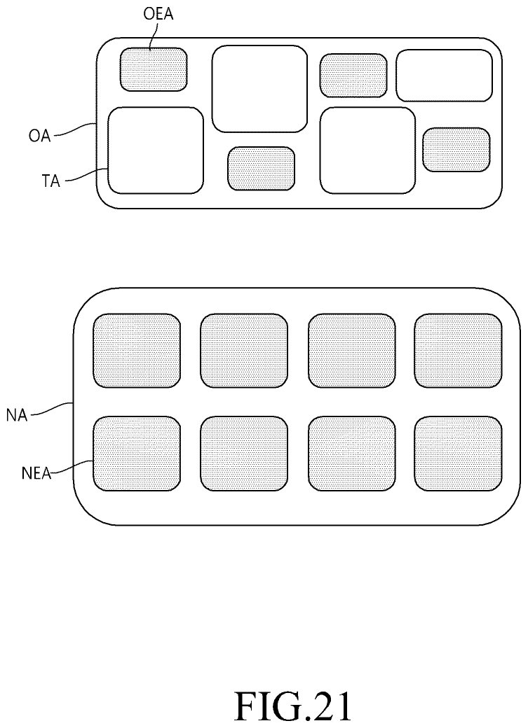

FIG. 21 is a plan view illustrating an example of a structure in which a plurality of subpixels overlap with each other for a pixel located in the optical area and the normal area in a display device according to exemplary embodiments of the present disclosure.

Referring to FIG. 21, in the display device 100 according to the exemplary embodiments of the present disclosure, a plurality of subpixels may be disposed to be overlapped with each other for a pixel disposed in the optical area OA, but subpixels may not overlap with each other in a pixel disposed in the normal area NA.

In this case, in the optical area OA, a plurality of subpixels may be disposed to overlap with each other in the optical emission area OEA excluding the transmission area TA.

In this case, the display device 100 of the present disclosure may be constituted so that a plurality of subpixels overlap with each other for a pixel in the normal area NA where the optical electronic device 11 is not located.

In this case, since the normal area NA does not include a transmission area, the area of the normal emission area NEA where the subpixels emit light may be formed widely.

The exemplary embodiments of the present disclosure may be described as follows.

A display panel according to the exemplary embodiments of the present disclosure may include an optical area including a transmission area and an optical emission area, and a normal area having a normal emission area at the periphery of the optical area, wherein the optical emission area includes a pixel in which a plurality of subpixels of different colors are stacked, wherein the plurality of subpixels emit light at different times.

The optical emission area may include a first subpixel including a first subpixel circuit and a first light emitting element emitting light of a first color, a second subpixel including a second subpixel circuit and a second light emitting element emitting light of a second color, and a third subpixel including a third subpixel circuit and a third light emitting element emitting light of a third color, wherein the first light emitting element to the third light emitting element are disposed to overlap with each other in an overlapping emission area.

The first subpixel circuit to the third subpixel circuit may be disposed so as not to overlap with each other.

The first light emitting element may include a first anode electrode, a first emission layer, and a first cathode electrode sequentially stacked, the second light emitting element located on the first light emitting element may include a second anode electrode, a second emission layer, and a second cathode electrode sequentially stacked, and the third light emitting element located on the second light emitting element may include a third anode electrode, a third emission layer, and a third cathode electrode sequentially stacked.

Each of the first emission layer to the third emission layer may include a hole injection layer, a hole transport layer, an electron blocking layer, an emission material layer, a hole blocking layer, an electron transport layer, and an electron injection layer.

A capping layer may be disposed on an upper portion of the second cathode electrode, and is made of an organic material having a low molecular structure.

The first anode electrode to the third anode electrode may extend outwardly from the overlapping emission area along different directions, and the first cathode electrode to the third cathode electrode may extend outwardly from the overlapping emission area along the same direction.

The first cathode electrode to the third cathode electrode may be electrically connected at the outside of the overlapping emission area.

The first anode electrode and the second anode electrode may extend outwardly from the overlapping emission area along different directions, and wherein first cathode electrode and the second cathode electrode may extend outwardly from the overlapping emission area along different directions.

The first light emitting element and the second light emitting element may share a cathode electrode, and the second light emitting element and the third light emitting element may share an anode electrode.

The first light emitting element may include a first anode electrode, a first emission layer, and a first cathode electrode sequentially stacked, the second light emitting element located on the first light emitting element may include a second anode electrode, a second emission layer, and a second cathode electrode sequentially stacked, and the third light emitting element located on the second light emitting element may include a third anode electrode, a third emission layer, and a third cathode electrode sequentially stacked.

The first emission layer may include a first hole injection layer, a first hole transport layer, a first electron blocking layer, a first emission material layer, a first hole blocking layer, a first electron transport layer, and a first electron injection layer sequentially stacked.

The first emission layer does not comprise the first electron blocking layer and the first hole blocking layer

The second emission layer may include a second electron injection layer, a second electron transport layer, a second hole blocking layer, a second emission material layer, a second electron blocking layer, a second hole transport layer, and a second hole injection layer sequentially stacked.

The second emission layer does not comprise the second electron blocking layer and the second hole blocking layer.

The third emission layer may include a third hole injection layer, a third hole transport layer, a third electron blocking layer, a third emission material layer, a third hole blocking layer, a third electron transport layer, and a third electron injection layer sequentially stacked.

The third emission layer does not comprise the third electron blocking layer and the third hole blocking layer.

The first anode electrode and the second anode electrode may extend in a direction parallel to a pixel high-potential voltage line supplied with a pixel high-potential voltage, and the first cathode electrode and the second cathode electrode may extend in a direction parallel to a pixel low-potential voltage line supplied with a pixel low-potential voltage.

The first subpixel may be supplied with a first pixel high-potential voltage and a first pixel low-potential voltage, and the second subpixel may be supplied with a second pixel high-potential voltage and the first pixel low-potential voltage, and the third subpixel may be supplied with the second pixel high-potential voltage and a second pixel low-potential voltage.

The first subpixel to the third subpixel may emit light at different times according to the first pixel high-potential voltage, the second pixel high-potential voltage, the first pixel low-potential voltage, and the second pixel low-potential voltage.

The first light emitting element may emit light if the first pixel high-potential voltage is greater than the first pixel low-potential voltage, the second light emitting element may emit light if the second pixel high-potential voltage is greater than the first pixel low-potential voltage, and the third light emitting element may emit light if the second pixel high-potential voltage is greater than the second pixel low-potential voltage.

The normal emission area may include a pixel in which a plurality of subpixels of different colors are stacked, and the plurality of subpixels may emit light at different times.

The normal emission area may include a first subpixel including a first subpixel circuit and a first light emitting element emitting light of a first color, a second subpixel including a second subpixel circuit and a second light emitting element emitting light of a second color, and a third subpixel including a third subpixel circuit and a third light emitting element emitting light of a third color. In this case, the first light emitting element to the third light emitting element may be disposed to overlap with each other in an overlapping emission area.

The first light emitting element may include a first anode electrode, a first emission layer, and a first cathode electrode sequentially stacked, the second light emitting element located on the first light emitting element may include a second anode electrode, a second emission layer, and a second cathode electrode sequentially stacked, and the third light emitting element located on the second light emitting element may include a third anode electrode, a third emission layer, and a third cathode electrode sequentially stacked.

The first light emitting element may include a first anode electrode, a first emission layer, and a first cathode electrode sequentially stacked, the second light emitting element located on the first light emitting element may include the first cathode electrode, a second emission layer, and a second anode electrode sequentially stacked, and the third light emitting element located on the second light emitting element includes the second anode electrode, a third emission layer, and a second cathode electrode sequentially stacked.

A display device according to exemplary embodiments of the present disclosure may include a display panel including an optical area having a transmission area and an optical emission area, and a normal area having a normal emission area at an outer periphery of the optical area, and a driving circuit configured to drive the display panel, wherein the optical emission area includes a pixel in which a plurality of subpixels of different colors are stacked, wherein the plurality of subpixels emit light at different times.

A display device according to exemplary embodiments of the present disclosure may include an optical area including a transmission area and an optical emission area, wherein the optical emission area comprises a pixel in which a first subpixel, a second subpixel and a third subpixel of different colors are stacked, the first subpixel is supplied with a first pixel high-potential voltage and a first pixel low-potential voltage, the second subpixel is supplied with a second pixel high-potential voltage and the first pixel low-potential voltage, and the third subpixel is supplied with the second pixel high-potential voltage and a second pixel low-potential voltage

The above description has been presented to enable any person skilled in the art to make and use the technical idea of the present disclosure and has been provided in the context of a particular application and its requirements. Various modifications, additions and substitutions to the described embodiments will be readily apparent to those skilled in the art, and the general principles defined herein may be supplied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display panel comprising:
an optical area including a transmission area and an optical emission area; and
a normal area including a normal emission area at a periphery of the optical area,
wherein the optical emission area comprises a pixel in which a plurality of subpixels of different colors are stacked,
wherein the plurality of subpixels emit light at different times.

2. The display panel of claim 1, wherein the optical emission area includes:
a first subpixel including a first subpixel circuit and a first light emitting element for emitting light of a first color;
a second subpixel including a second subpixel circuit and a second light emitting element for emitting light of a second color; and
a third subpixel including a third subpixel circuit and a third light emitting element for emitting light of a third color,
wherein the first light emitting element, the second light emitting element, and the third light emitting element are disposed to overlap with each other in an overlapping emission area.

3. The display panel of claim 2, wherein the first subpixel circuit, the second subpixel circuit, and the third subpixel circuit are disposed so as not to overlap with each other.

4. The display panel of claim 2, wherein the first light emitting element includes a first anode electrode, a first emission layer, and a first cathode electrode sequentially stacked,
wherein the second light emitting element located on the first light emitting element includes a second anode electrode, a second emission layer, and a second cathode electrode sequentially stacked,
wherein the third light emitting element located on the second light emitting element includes a third anode electrode, a third emission layer, and a third cathode electrode sequentially stacked.

5. The display panel of claim 4, wherein each of the first emission layer to the third emission layer includes a hole injection layer, a hole transport layer, an electron blocking layer, a emission material layer, a hole blocking layer, an electron transport layer, and an electron injection layer.

6. The display panel of claim 4, wherein the first anode electrode, the second anode electrode, and the third anode electrode extend outwardly from the overlapping emission area along different directions,
wherein the first cathode electrode, the second cathode electrode, and the third cathode electrode extend outwardly from the overlapping emission area along a same direction.

7. The display panel of claim 6, wherein the first cathode electrode, the second cathode electrode, and the third cathode electrode are electrically connected at an outside of the overlapping emission area.

8. The display panel of claim 4, wherein the first anode electrode and the second anode electrode extend outwardly from the overlapping emission area along different directions, and
wherein first cathode electrode and the second cathode electrode extend outwardly from the overlapping emission area along different directions.

9. The display panel of claim 2, wherein the first light emitting element and the second light emitting element share a cathode electrode,
wherein the second light emitting element and the third light emitting element share an anode electrode.

10. The display panel of claim 9, wherein the first light emitting element includes a first anode electrode, a first emission layer, and a first cathode electrode sequentially stacked,
wherein the second light emitting element located on the first light emitting element includes the first cathode electrode, a second emission layer, and a second anode electrode sequentially stacked,
wherein the third light emitting element located on the second light emitting element includes the second anode electrode, a third emission layer, and a second cathode electrode sequentially stacked.

11. The display panel of claim 10, wherein the first anode electrode and the second anode electrode extend in a direction parallel to a pixel high-potential voltage line supplied with a pixel high-potential voltage,
wherein the first cathode electrode and the second cathode electrode extend in a direction parallel to a pixel low-potential voltage line supplied with a pixel low-potential voltage.

12. The display panel of claim 10, wherein the first subpixel is supplied with a first pixel high-potential voltage and a first pixel low-potential voltage,
wherein the second subpixel is supplied with a second pixel high-potential voltage and the first pixel low-potential voltage,
wherein the third subpixel is supplied with the second pixel high-potential voltage and a second pixel low-potential voltage.

13. The display panel of claim 12, wherein the first subpixel, the second subpixel, and the third subpixel emit light at different times according to the first pixel high-potential voltage, the second pixel high-potential voltage, the first pixel low-potential voltage, and the second pixel low-potential voltage.

14. The display panel of claim 1, wherein the normal emission area includes a pixel in which a plurality of subpixels of different colors are stacked,
wherein the plurality of subpixels emit light at different times.

15. The display panel of claim 14, wherein the normal emission area includes:
a first subpixel including a first subpixel circuit and a first light emitting element emitting light of a first color;
a second subpixel including a second subpixel circuit and a second light emitting element emitting light of a second color; and
a third subpixel including a third subpixel circuit and a third light emitting element emitting light of a third color,
wherein the first light emitting element, the second light emitting element, and the third light emitting element are disposed to overlap with each other in an overlapping emission area.

16. The display panel of claim 15, wherein the first light emitting element includes a first anode electrode, a first emission layer, and a first cathode electrode sequentially stacked,
wherein the second light emitting element located on the first light emitting element includes a second anode electrode, a second emission layer, and a second cathode electrode sequentially stacked,
wherein the third light emitting element located on the second light emitting element includes a third anode electrode, a third emission layer, and a third cathode electrode sequentially stacked.

17. The display panel of claim 15, wherein the first light emitting element includes a first anode electrode, a first emission layer, and a first cathode electrode sequentially stacked,
wherein the second light emitting element located on the first light emitting element includes the first cathode electrode, a second emission layer, and a second anode electrode sequentially stacked,
wherein the third light emitting element located on the second light emitting element includes the second anode electrode, a third emission layer, and a second cathode electrode sequentially stacked.

18. A display device comprising:
a display panel including an optical area having a transmission area and an optical emission area, and a normal area having a normal emission area at an outer periphery of the optical area; and
a driving circuit configured to drive the display panel,
wherein the optical emission area includes a pixel in which a plurality of subpixels of different colors are stacked,
wherein the plurality of subpixels emit light at different times.

19. A display panel comprising:
an optical area including a transmission area and an optical emission area,
wherein the optical emission area comprises a pixel in which a first subpixel, a second subpixel and a third subpixel of different colors are stacked,
the first subpixel is supplied with a first pixel high-potential voltage and a first pixel low-potential voltage,
the second subpixel is supplied with a second pixel high-potential voltage and the first pixel low-potential voltage, and
the third subpixel is supplied with the second pixel high-potential voltage and a second pixel low-potential voltage.
